(19) United States
(12) Patent Application Publication
(10) Pub. No.: US 2026/0082751 A1
(43) Pub. Date: Mar. 19, 2026

(54) DISPLAY DEVICE

(71) Applicant: LG Display Co., Ltd., Seoul (KR)

(72) Inventors: Soyi Lee, Paju-si (KR); Youngin Jang, Paju-si (KR); Soyoung Lee, Seoul (KR); HyunGon Kim, Seoul (KR); Juhyun Nam, Seoul (KR)

(73) Assignee: LG Display Co., Ltd., Seoul (KR)

(21) Appl. No.: 19/313,302

(22) Filed: Aug. 28, 2025

(30) Foreign Application Priority Data
Sep. 19, 2024 (KR) 10-2024-0126916

(51) Int. Cl. H10H 29/49; H10H 29/41

(52) U.S. Cl. CPC H10H 29/49; H10H 29/41

(57) ABSTRACT

A display device can include a plurality of sub-pixels. Each sub-pixel can include a driving transistor disposed on a substrate, a power line disposed on the substrate, and a reflective electrode disposed on the driving transistor and the power line. The reflective electrode can include a first reflective electrode and a second reflective electrode spaced apart from each other. Further, the first reflective electrode is electrically connected to the driving transistor, and the second reflective electrode is electrically connected to the power line. The display device can further include an adhesive layer disposed on the reflective electrode, and a light emitting diode disposed on the adhesive layer.

### CROSS-REFERENCE TO RELATED APPLICATIONS

This application claims priority to Korean Patent Application No. 10-2024-0126916 filed on Sep. 19, 2024, in the Korean Intellectual Property Office, the disclosure of which is hereby expressly incorporated by reference into the present application.

### BACKGROUND

### Field

The present disclosure relates to a display device, and more particularly, to a display device with a reduced line resistance.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY OF THE DISCLOSURE

An object to be achieved by the present disclosure is to provide a display device in which a process cost and time are saved by reducing the number of masks needed for the process.

Another object to be achieved by the present disclosure is to provide a display device with a reduced line resistance.

Another object to be achieved by the present disclosure is to provide a display device which detects whether the light emitting diode is defective regardless of whether the driving transistor is defective.

Another object to be achieved by the present disclosure is to provide a display device in which a defect due to the oxidization of the reflective electrode is minimized.

Another object to be achieved by the present disclosure is to provide a display device in which a defect due to the oxidization of the pad electrode is minimized.

Another object to be achieved by the present disclosure is to provide a display device in which the connection defect due to the residual film generating during the process is minimized to improve the electrical connection.

Another object to be achieved by the present disclosure is to provide a display device which is easily repaired.

Objects of the present disclosure are not limited to the above-mentioned objects, and other objects, which are not mentioned above, can be clearly understood by those skilled in the art from the following descriptions.

A display device according to aspects of the present disclosure comprises a plurality of sub-pixels, and each of the plurality of sub-pixels comprises: a substrate; a driving transistor disposed on the substrate; a power line disposed on the substrate; a reflective electrode disposed on the driving transistor and the power line, wherein the reflective electrode comprises a first reflective electrode and a second reflective electrode spaced apart from each other, the first reflective electrode is electrically connected to the driving transistor, and the second reflective electrode is electrically connected to the power line; an adhesive layer disposed on the reflective electrode; a light emitting diode disposed on the adhesive layer; a first planarization layer disposed on the adhesive layer and enclosing a part of a side edge of the light emitting diode; a first connection electrode and a second connection electrode disposed on the first planarization layer and spaced apart from each other; a second planarization layer disposed on the first planarization layer, the first connection electrode and the second connection electrode; and a third connection electrode disposed on the second planarization layer, wherein the first reflective electrode is connected to the light emitting diode by the first connection electrode, and wherein the second reflective electrode is connected to the light emitting diode by the second connection electrode and the third connection electrode.

A display device according to aspects of the present disclosure comprises a plurality of pixels, and each of the plurality of pixels comprising a plurality of sub-pixels, wherein each of the plurality of pixels comprises a first contact region and a second contact region adjacent to each other, wherein each of the plurality of sub-pixels comprises: a substrate; a driving transistor disposed on the substrate; a power line disposed on the substrate; a reflective electrode disposed on the driving transistor and the power line, wherein the reflective electrode comprises a first reflective electrode and a second reflective electrode spaced apart from each other, the first reflective electrode is electrically connected to the driving transistor, and the second reflective electrode is electrically connected to the power line; an adhesive layer disposed on the reflective electrode; a light emitting diode disposed on the adhesive layer; a first planarization layer disposed on the adhesive layer and enclosing a part of a side edge of the light emitting diode; a first connection electrode and a second connection electrode disposed on the first planarization layer and spaced apart from each other; a second planarization layer disposed on the first planarization layer, the first connection electrode and the second connection electrode; and a third connection electrode disposed on the second planarization layer, wherein the first reflective electrode is connected to the light emitting diode by the first connection electrode, and the third connection electrode is electrically connected to the light emitting diode, wherein, in the first contact region, the second reflective electrode is electrically connected to the second connection electrode and the third connection electrode, wherein, in the second contact region, the third connection electrode is electrically connected to the second connection electrode.

A display device according to aspects of the present disclosure comprises a plurality of sub-pixels, and each of the plurality of sub-pixels comprises: a substrate; a driving transistor disposed on the substrate; a first reflective electrode disposed on the driving transistor and connected to the driving transistor; an adhesive layer disposed on the first reflective electrode; a light emitting diode disposed on the adhesive layer; a first planarization layer disposed on the adhesive layer and enclosing a part of a side edge of the light emitting diode; a first connection electrode disposed on the first planarization layer; a second planarization layer disposed on the first planarization layer and the first connection electrode; and a bank layer disposed on the second planarization layer, wherein the adhesive layer comprises a contact hole of the adhesive layer, the first planarization layer comprises a contact hole of the first planarization layer, and wherein the second planarization layer comprises a contact hole of the second planarization layer overlapped with the contact hole of the adhesive layer and the contact hole of the first planarization layer, wherein the display device further comprises: a first conductive pattern disposed on the first planarization layer and connected to the first reflective electrode by the contact hole of the adhesive layer and the contact hole of the first planarization layer; and a second conductive pattern disposed between the second planarization layer and the bank layer, and electrically connected to the first conductive pattern by the contact hole of the adhesive layer, the contact hole of the first planarization layer and the contact hole of the second planarization layer, and wherein the second conductive pattern directly contacts the bank layer.

Other detailed matters of the example embodiments are included in the detailed description and the drawings.

According to the example embodiment of the present disclosure, the second connection electrode is utilized as a protection layer of the second reflective electrode to minimize the oxidation of the first reflective electrode.

According to the example embodiment of the present disclosure, the third conductive layer of the pad electrode is utilized as a protection layer of the second conductive layer to minimize the oxidation of the second conductive layer.

According to the example embodiment of the present disclosure, the third connection electrode is electrically connected to a power line through the second connection electrode and the second reflective electrode to minimize the resistance between the power line and the third connection electrode.

According to the example embodiment of the present disclosure, the third connection electrode is additionally connected to the second connection electrode through a separate contact hole to minimize the resistance between the power line and the third connection electrode.

According to the example embodiment of the present disclosure, a lighting test signal is applied to the light emitting diode without passing through the driving transistor to detect whether the light emitting diode is defective regardless of whether the driving transistor is defective.

According to the example embodiment of the present disclosure, the number of times of a formation process of a contact hole of an adhesive layer is reduced to reduce the number of masks needed for the process, thereby saving a process cost and a time and implementing process optimization.

According to the example embodiment of the present disclosure, a potential defect due to the corrosion of the wiring line is minimized and the lifespan of the display device is improved and to be driven at a low power in terms of reduction of a production energy.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an example embodiment of the present disclosure;

FIG. 2A is a partial cross-sectional view of a display device according to an example embodiment of the present disclosure;

FIG. 2B is a perspective view of a tiling display device according to an example embodiment of the present disclosure;

FIG. 3 is an enlarged plan view of a pixel of a display device according to an example embodiment of the present disclosure;

FIGS. 4A to 4C are plan views of a light emitting diode of a display device according to an example embodiment of the present disclosure;

FIG. 5 is a cross-sectional view taken along line V-V′ of FIG. 3;

FIG. 6 is a cross-sectional view taken along line VI-VI′ of FIG. 2A;

FIGS. 7A to 7F are process diagrams of a manufacturing method of a display device according to an example embodiment of the present disclosure; and

FIGS. 8A to 8F are process diagrams of a manufacturing method of a display device according to an example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be directly on the other element or interposed therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure. Further, the term “can” fully encompasses all the meanings and coverages of the term “may” and vice versa.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device/apparatus according to all embodiments of the present disclosure are operatively coupled and configured.

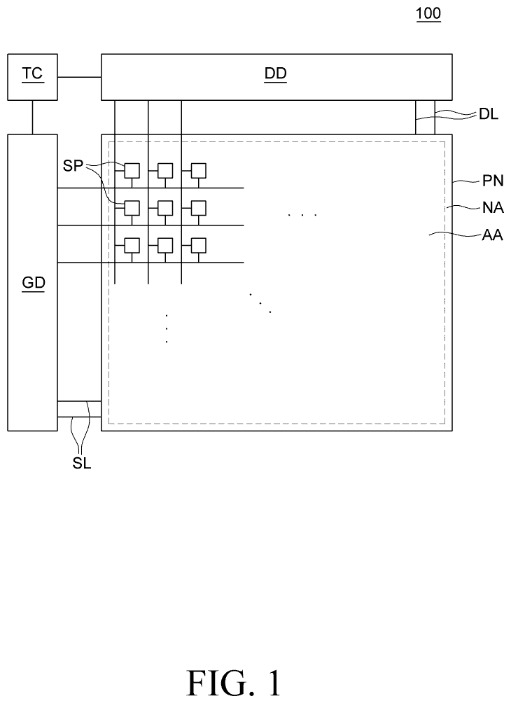

FIG. 1 is a schematic diagram of a display device according to an example embodiment of the present disclosure. In FIG. 1, for the convenience of description, among various components of the display device 100, a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD can supply the converted data voltage to the plurality of data lines DL.

The timing controller TC aligns image data input from the outside to supply the image data to the data driver DD. The timing controller TC can generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, each of the plurality of sub pixels SP can be connected to a high potential power line, a low potential power line, and a reference line.

In the display panel PN, an active area AA and a non-active area NA enclosing the active area AA can be defined.

The active area AA is an area in which images are displayed in the display device 100. In the active area AA, a plurality of sub pixels SP which configures a plurality of pixels PX and a circuit for driving the plurality of sub pixels SP can be disposed. The plurality of sub pixels SP is a minimum unit which configures the active area AA and n sub pixels SP can form one pixel PX. In each of the plurality of sub pixels SP, a light emitting diode and a thin film transistor for driving the light emitting diode can be disposed. The plurality of light emitting diodes can be defined in different manners depending on the type of the display panel PN. For example, when the display panel PN is an inorganic light emitting display panel, the light emitting diode can be a light emitting diode (LED) or a micro light emitting diode (micro LED).

In the active area AA, a plurality of signal lines which transmits various signals to the plurality of sub pixels SP is disposed. For example, the plurality of signal lines can include a plurality of data lines DL which supplies a data voltage to each of the plurality of sub pixels SP and a plurality of scan lines SL which supplies a gate voltage to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line and a high potential power line can be further disposed, but are not limited thereto.

The non-active area NA is an area where images are not displayed so that the non-active area NA can be defined as an area extending from the active area AA. In the non-active area NA, a link line which transmits a signal to the sub pixel SP of the active area AA, a pad electrode, or a driving IC, such as a gate driver IC or a data driver IC, can be disposed. The non-active area NA can be located on a rear surface of the display panel PN, for example, a surface on which the sub pixels SP are not disposed or can be omitted, and is not limited to as illustrated in the drawing.

In the meantime, a driver, such as a gate driver GD, a data driver DD, and a timing controller TC, can be connected to the display panel PN in various ways. For example, the gate driver GD can be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board and can be electrically connected to the display panel PN by bonding the flexible film and the printed circuit board to a pad electrode formed in the non-active area NA of the display panel PN. If the gate driver GD is mounted in the GIP manner and the data driver DD and the timing controller TC transmit a signal to the display panel PN through a pad electrode of the non-active area NA, an area of the non-active area NA to dispose the gate driver GD and the pad electrode needs to be ensured. By doing this, a bezel can be increased.

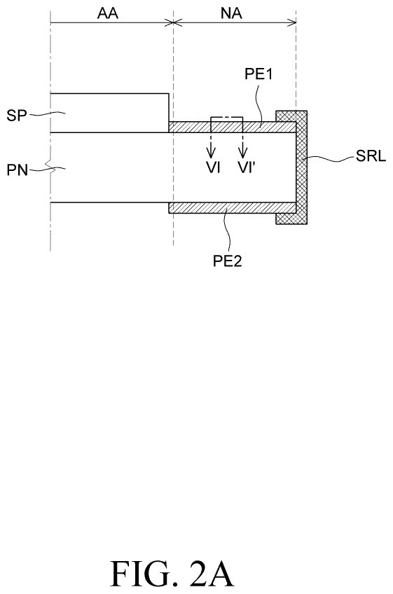

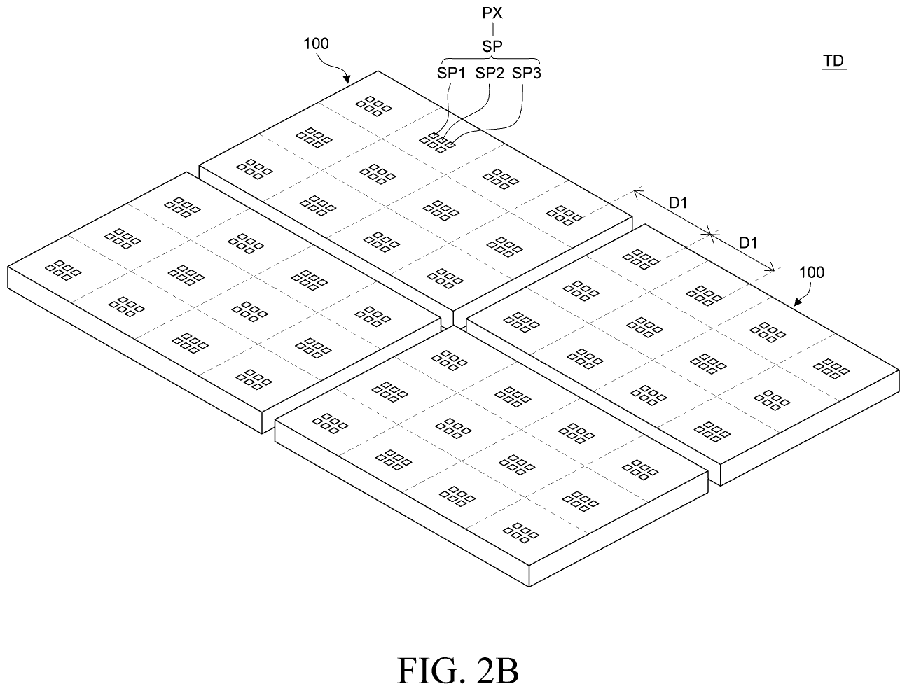

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA can be minimized on the front surface of the display panel PN. For example, when the gate driver GD, the data driver DD, and the timing controller TC are connected to the display panel PN as described above, a zero bezel in which there is no bezel can be substantially implemented, which will be described in more detail with reference to FIGS. 2A and 2B.

FIG. 2A is a partial cross-sectional view of a display device according to an example embodiment of the present disclosure. FIG. 2B is a perspective view of a tiling display device according to an example embodiment of the present disclosure.

Referring to FIGS. 2A and 2B, in the non-active area NA of the display panel PN, a plurality of pad electrodes for transmitting various signals to the plurality of sub pixels SP is disposed. For example, in a non-active area NA on the front surface of the display panel PN, a first pad electrode PE1 which transmits a signal to the plurality of sub pixels SP is disposed. In a non-active area NA on the rear surface of the display panel PN, a second pad electrode PE2 which is electrically connected to a driving component, such as a flexible film and the printed circuit board, is disposed.

For example, the display panel PN can be formed by bonding two or more substrates in a vertical direction. At this time, the first pad electrode PE1 and the second pad electrode PE2 can be disposed on different substrates. For example, the first pad electrode PE1 can be disposed on a front surface of an upper substrate. The second pad electrode PE2 can be disposed on a rear surface of a lower substrate. For example, the display panel PN can be formed by bonding the upper substrate with the first pad electrode PE1 disposed on the front surface and the lower substrate with the second pad electrode PE2 disposed on the rear surface, but is not limited thereto.

In this case, various signal lines connected to the plurality of sub pixels SP, for example, a scan line SL or a data line DL extends from the active area AA to the non-active area NA to be electrically connected to the first pad electrode PE1.

The side line SRL is disposed along a side surface of the display panel PN. The side line SRL can electrically connect the first pad electrode PE1 on the front surface of the display panel PN and the second pad electrode PE2 on the rear surface of the display panel PN. Therefore, a signal from a driving component on the rear surface of the display panel PN can be transmitted to the plurality of sub pixels SP through the second pad electrode PE2, the side line SRL, and the first pad electrode PE1. Accordingly, a signal transmitting path is formed from the front surface of the display panel PN to the side surface and the rear surface to minimize an area of the non-active area NA of the display panel PN.

Referring to FIG. 2B, a tiling display device TD having a large screen size can be implemented by connecting a plurality of display devices 100. At this time, when the tiling display device TD is implemented using a display device 100 with a minimized bezel as illustrated in FIG. 2B, a seam area in which an image between the display devices 100 is not displayed is minimized so that a display quality can be improved.

For example, the plurality of sub pixels SP can form one pixel PX and a distance D1 between an outermost pixel PX of one display device 100 and an outermost pixel PX of another display device 100 adjacent to one display device can be implemented to be equal to a distance D1 between pixels PX in one display device 100. Accordingly, the interval of the pixels PX between the display devices 100 is constantly configured to minimize the seam area.

However, FIGS. 2A and 2B are illustrative so that the display device 100 according to the example embodiment of the present disclosure can be a general display device with a bezel, but is not limited thereto.

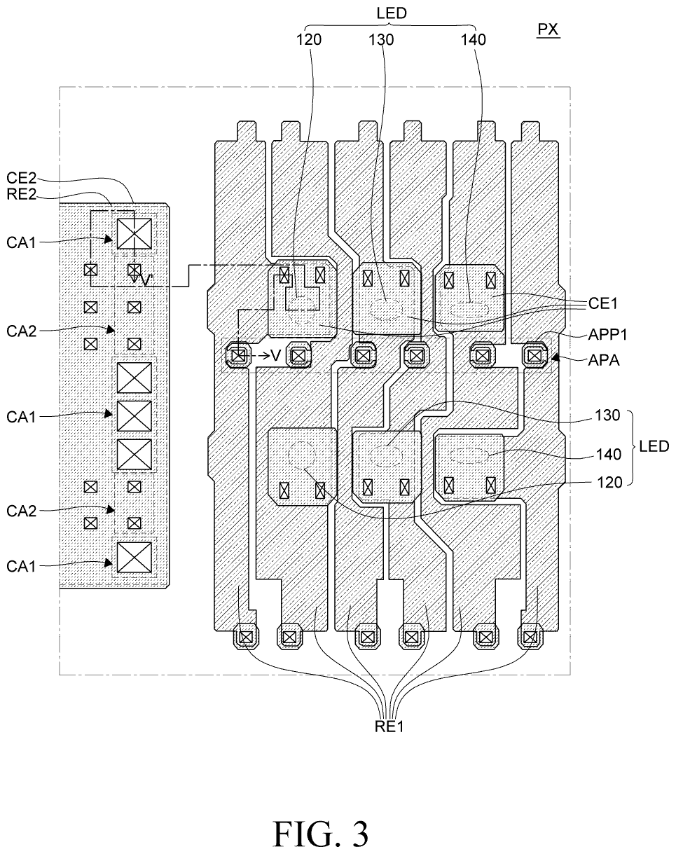

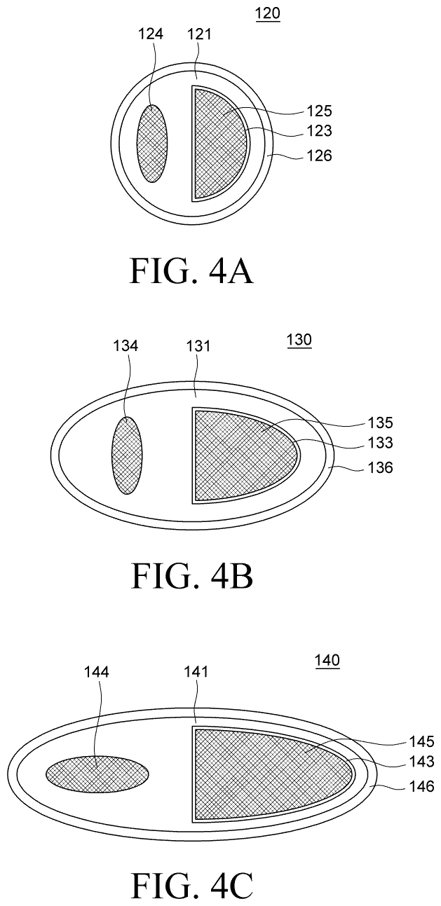

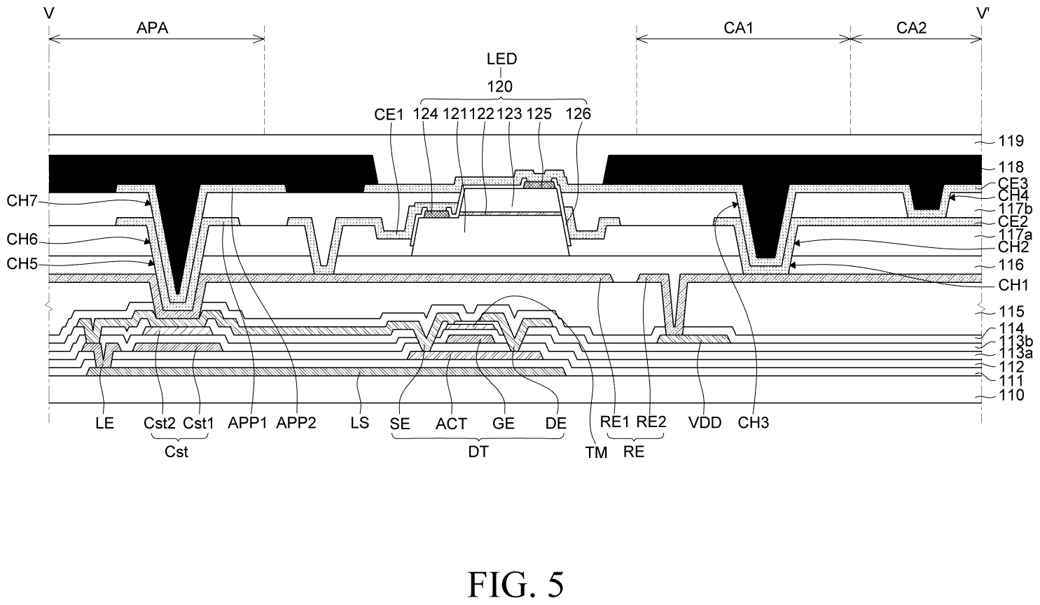

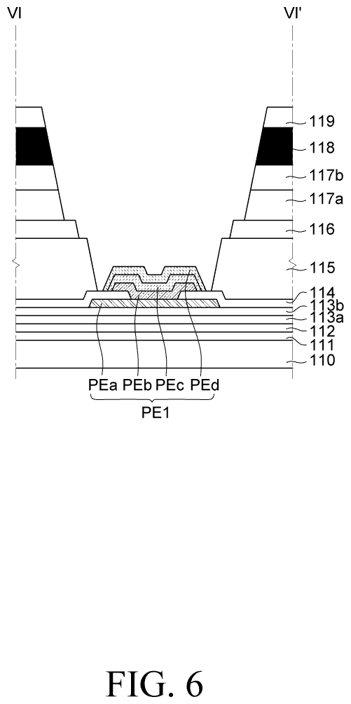

FIG. 3 is an enlarged plan view of a pixel of a display device according to an example embodiment of the present disclosure. FIGS. 4A to 4C are plan views of a light emitting diode of a display device according to an example embodiment of the present disclosure. FIG. 5 is a cross-sectional view taken along line V-V′ of FIG. 3. FIG. 6 is a cross-sectional view taken along line VI-VI′ of FIG. 2A. In FIG. 3, among the configurations of the display device 100, a first reflective electrode RE1, a second reflective electrode RE2, a first connection electrode CE1, a second connection electrode CE2, a first lighting test pattern APP1, and a light emitting diode LED are illustrated. In FIG. 5, a cross-sectional view for a first sub pixel SP1 including a first light emitting diode 120 is illustrated, which is the same as a cross-section of a second sub pixel SP2 including a second light emitting diode 130 and a cross-section of a third sub pixel SP3 including a third light emitting diode 140.

First, referring to FIGS. 2B and 3, the display panel PN includes a plurality of pixels PX which is formed by a plurality of sub pixels SP. Each of the plurality of sub pixels SP includes a light emitting diode LED and a pixel circuit to independently emit light. One pixel PX can include a first sub pixel SP1, a second sub pixel SP2, and a third sub pixel SP3. For example, one pixel PX can include one first sub pixel SP1, one second sub pixel SP2, and one third sub pixel SP3. At this time, the first sub pixel SP1 can be a red sub pixel, the second sub pixel SP2 can be a green sub pixel, and the third sub pixel SP3 can be a blue sub pixel, but they are not limited thereto.

A plurality of light emitting diodes LED can be disposed in the plurality of sub pixels SP. Specifically, the plurality of light emitting diodes LED includes a first light emitting diode 120, a second light emitting diode 130, and a third light emitting diode 140. The first light emitting diode 120 can be disposed in the first sub pixel SP1, the second light emitting diode 130 can be disposed in the second sub pixel SP2, and the third light emitting diode 140 can be disposed in the third sub pixel SP3. For example, the first light emitting diode 120 can be a red light emitting diode, the second light emitting diode 130 can be a green light emitting diode, and the third light emitting diode 140 can be a blue light emitting diode.

In the meantime, referring to FIGS. 3 to 4C, the first light emitting diode 120, the second light emitting diode 130, and the third light emitting diode 140 can be formed with different shapes. For example, a planar shape of the first light emitting diode 120 can be a circular shape and planar shapes of the second light emitting diode 130 and the third light emitting diode 140 can be oval shapes. At this time, the second light emitting diode 130 and the third light emitting diode 140 can have different sizes to have different oval shapes. In the meantime, a major axis direction of the second light emitting diode 130 and the third light emitting diode 140 can be the same, but the present disclosure is not limited thereto.

The first light emitting diode 120 can include a first semiconductor layer 121, an emission layer 122, a second semiconductor layer 123, a first electrode 124, a second electrode 125, and a passivation film 126. At this time, a planar shape of the first semiconductor layer 121 of the first light emitting diode 120 can be a circular shape and a planar shape of the second semiconductor layer 123 can be a semi-circular shape. A planar shape of the first electrode 124 can be an oval shape. The second electrode 125 can be formed to have a semi-circular shape which is the same as a top surface of the second semiconductor layer 123.

The second light emitting diode 130 can include a first semiconductor layer 131, an emission layer, a second semiconductor layer 133, a first electrode 134, a second electrode 135, and a passivation film 136. At this time, planar shapes of the first semiconductor layer 131 and the first electrode 134 of the second light emitting diode 130 can be oval shapes. At this time, a major axis direction of the first semiconductor layer 131 can be configured to be different from a major axis direction of the first electrode 134. For example, when the first semiconductor layer 131 has an oval shape having a major axis in a horizontal direction, the first electrode 134 can have an oval shape having a major axis in the vertical direction. For example, the first electrode 134 can be disposed in one end portion of the first semiconductor layer 131 in the major axis direction, on the top surface of the first semiconductor layer 131. The planar shapes of the second semiconductor layer 133 and the second electrode 135 can be truncated oval shapes.

The third light emitting diode 140 can include a first semiconductor layer 141, an emission layer, a second semiconductor layer 143, a first electrode 144, a second electrode 145, and a passivation film 146. At this time, planar shapes of the first semiconductor layer 141 and the first electrode 144 of the third light emitting diode 140 can be oval shapes. Unlike the second light emitting diode 130, in the third light emitting diode 140, the major axis direction of the first semiconductor layer 141 and the major axis direction of the first electrode 144 can be configured to be the same. For example, the first electrode 144 can be disposed in one end portion of the first semiconductor layer 141 in the major axis direction, on the top surface of the first semiconductor layer 141. The planar shapes of the second semiconductor layer 143 and the second electrode 145 can be truncated oval shapes.

For example, in the display device 100 according to the example embodiment of the present disclosure, the first light emitting diode 120, the second light emitting diode 130, and the third light emitting diode 140 are configured to have different shapes, respectively, to distinguish the plurality of light emitting diodes LED. For example, when the light emitting diode LED is self-assembled, the plurality of light emitting diodes LED is formed to have different shapes to be self-assembled in a position corresponding to each of the plurality of sub pixels SP. However, the shapes of the plurality of light emitting diodes LED are illustrative, so that it is not limited thereto.

In the meantime, referring to FIG. 3, in the plurality of pixels PX of the display panel PN of the display device 100 according to the example embodiment of the present disclosure, the first contact area CA1, the second contact area CA2, and the lighting test area APA can be defined.

The first contact area CA1 and the second contact area CA2 can be areas in which the power line VDD and the third connection electrode CE3 are electrically connected. For example, in the first contact area CA1, the third connection electrode CE3 can be electrically connected to the power line through the second reflective electrode RE2 and the second connection electrode CE2. In the second contact area CA2, the third connection electrode CE3 extending from the first contact area CA1 is additionally connected to the second connection electrode CE2 extending from the first contact area CA1 to be electrically connected to the power line.

The lighting test area APA can be an area in which a lighting test signal is transmitted to detect whether the light emitting diode LED is defective. For example, in the lighting test area APA, a first lighting test pattern APP1 and a second lighting test pattern APP2 can transmit a lighting test signal to the first electrodes 124, 134, and 144 of the light emitting diodes LED through the first reflective electrode RE1 without passing through the driving transistor DT. Therefore, whether the light emitting diode LED is defective can be detected regardless of the defect of the driving transistor. A detailed description with regard to this will be made with reference to FIG. 5 to be described below.

Next, referring to FIGS. 5 and 6 together, in each of the plurality of sub pixels SP of the display panel PN of the display device 100 according to the example embodiment of the present disclosure, a substrate 110, a buffer layer 111, a gate insulating layer 112, a first interlayer insulating layer 113a, a second interlayer insulating layer 113b, a passivation layer 114, an over coating layer 115, an adhesive layer 116, a first planarization layer 117a, a second planarization layer 117b, a bank 118, a third planarization layer 119, a driving transistor DT, a light emitting diode LED, a reflective electrode RE, a light shielding layer LS, an auxiliary electrode LE, a first connection electrode CE1, a second connection electrode CE2, a third connection electrode CE3, a capacitor Cst, an intermediate electrode TM, and a first pad electrode PE1 can be disposed.

First, the substrate 110 is a component for supporting various components included in the display device 100 and can be formed of an insulating material. For example, the substrate 110 can be formed of glass or resin. Further, the substrate 110 can be configured to include a polymer or plastic or can be formed of a material having flexibility.

The light shielding layer LS can be disposed in each of the plurality of sub pixels SP on the substrate 110. The light shielding layer LS blocks light incident onto an active layer ACT of the driving transistor DT to be described below from a lower portion of the substrate 110. Light which is incident onto the active layer ACT of the driving transistor DT is blocked by the light shielding layer LS to minimize a leakage current.

The buffer layer 111 can be disposed on the substrate 110 and the light shielding layer LS. The buffer layer 111 can reduce permeation of moisture or impurities through the substrate 110. For example, the buffer layer 111 can be configured by a single layer or a double layer of silicon oxide (SiOₓ) or silicon nitride (SiNₓ), but is not limited thereto. However, the buffer layer 111 can be omitted depending on a type of substrate 110 or a type of transistor, but is not limited thereto.

The driving transistor DT can be disposed on the buffer layer 111. The driving transistor DT includes an active layer ACT, a gate electrode GE, a source electrode SE, and a drain electrode DE.

The active layer ACT can be disposed on the buffer layer 111. The active layer ACT can be formed of a semiconductor material, such as an oxide semiconductor, amorphous silicon, or polysilicon, but is not limited thereto.

The gate insulating layer 112 can be disposed on the active layer ACT. The gate insulating layer 112 is an insulating layer which insulates the active layer ACT from the gate electrode GE and can be configured by a single layer or a double layer of silicon oxide (SiOₓ) or silicon nitride (SiNₓ), but is not limited thereto.

The gate electrode GE can be disposed on the gate insulating layer 112. The gate electrode GE can be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113a and the second interlayer insulating layer 113b can be disposed on the gate electrode GE. In the gate insulating layer 112, the first interlayer insulating layer 113a, and the second interlayer insulating layer 113b, contact holes through which the source electrode SE and the drain electrode DE are connected to the active layer ACT, respectively, are formed. The first interlayer insulating layer 113a and the second interlayer insulating layer 113b are insulating layers for protecting a component below the first interlayer insulating layer 113a and the second interlayer insulating layer 113b and can be configured by a single layer or a double layer of silicon oxide (SiOₓ) or silicon nitride (SiNₓ), but are not limited thereto.

The source electrode SE and the drain electrode DE which are electrically connected to the active layer ACT can be disposed on the second interlayer insulating layer 113b. The source electrode SE and the drain electrode DE can be configured by a conductive material, such as copper (Cu), aluminum (Al), molybdenum (Mo), nickel (Ni), titanium (Ti), chrome (Cr), or an alloy thereof, but are not limited thereto.

In the meantime, in the present disclosure, it is described that the first interlayer insulating layer 113a and the second interlayer insulating layer 113b, for example, a plurality of insulating layers is disposed between the gate electrode GE and the source electrode SE and the drain electrode DE. However, only one insulating layer can be disposed between the gate electrode GE and the source electrode SE and the drain electrode DE, and is not limited thereto.

Further, the pixel circuit can further include a switching transistor, a sensing transistor, and an emission control transistor, in addition to the driving transistor DT, and is not limited thereto.

In the meantime, the intermediate electrode TM can be disposed on the first interlayer insulating layer 113a. The intermediate electrode TM is disposed so as to overlap the gate electrode GE of the driving transistor DT with the first interlayer insulating layer 113a therebetween to form a capacitor together with the gate electrode GE of the driving transistor DT, but is not limited thereto.

The auxiliary electrode LE can be disposed on the gate insulating layer 112. The auxiliary electrode LE is an electrode which electrically connects the light shielding layer LS below the buffer layer 111 to any one of the source electrode SE of the driving transistor DT and the drain electrode DE of the driving transistor DT on the second interlayer insulating layer 113b. For example, the light shielding layer LS is electrically connected to any one of the source electrode SE and the drain electrode DE of the driving transistor DT through the auxiliary electrode LE so as not to operate as a floating gate. Therefore, fluctuation of a threshold voltage of the driving transistor DT caused by the floated light shielding layer LS can be minimized. Even though in the drawing, the light shielding layer LS is connected to the source electrode SE of the driving transistor DT, the light shielding layer LS can also be connected to the drain electrode DE of the driving transistor DT, but is not limited thereto.

The capacitor Cst can be disposed on the gate insulating film 112. The capacitor Cst can include a first capacitor electrode Cst1 and a second capacitor electrode Cst2.

First, the first capacitor electrode Cst1 can be disposed on the gate insulating layer 112. The first capacitor electrode Cst1 can be disposed on the same layer as the gate electrode GE and can be formed of the same material, but is not limited thereto.

The second capacitor electrode Cst2 can be disposed on the first interlayer insulating layer 113a. The second capacitor electrode Cst2 can be disposed on the same layer as the intermediate electrode TM and can be formed of the same material, but is not limited thereto. The second capacitor electrode Cst2 can be disposed so as to overlap the first capacitor electrode Cst1 with the first interlayer insulating layer 113a therebetween. The second capacitor electrode Cst2 can be connected to the source electrode SE of the driving transistor DT.

Referring to FIG. 6, the first pad electrode PE1 can be disposed on the first interlayer insulating layer 113a. The first pad electrode PE1 can be configured by a plurality of conductive layers. For example, the first pad electrode PE1 can include a first conductive layer PEa, a second conductive layer PEb, a third conductive layer PEc, and a fourth conductive layer PEd.

First, the first conductive layer PEa can be disposed on the first interlayer insulating layer 113a. The first conductive layer PEa can be formed of the same conductive material as the source electrode SE and the drain electrode DE of the driving transistor DT and for example, can be configured by copper (Cu), aluminum (Al), molybdenum (Mo), nickel (Ni), titanium (Ti), chrome (Cr), or an alloy thereof, but is not limited thereto.

The second interlayer insulating layer 113b can be disposed on the first conductive layer PEa and the second conductive layer PEb can be disposed on the second interlayer insulating layer 113b. The second conductive layer PEb can be formed of the same conductive material as the plurality of reflective electrodes RE and for example, can be configured by silver (Ag), aluminum (Al), molybdenum (Mo), or an alloy thereof, but is not limited thereto.

The third conductive layer PEc can be disposed on the second conductive layer PEb. The third conductive layer PEc can be disposed so as to cover the end of the second conductive layer PEb to protect the second conductive layer PEb, thereby suppressing the oxidation of the second conductive layer PEb. The third conductive layer PEc can be formed of the same conductive material as the first connection electrode CE1 and the second connection electrode CE2, and for example, a transparent conductive material, such as indium tin oxide (ITO) or indium zinc oxide (IZO), but is not limited thereto.

The fourth conductive layer PEd can be disposed on the third conductive layer PEc. The fourth conductive layer PEd can be disposed so as to cover the end of the third conductive layer PEc. The fourth conductive layer PEd protects the second conductive layer PEb together with the third conductive layer PEc to suppress the oxidation of the second conductive layer PEb. The fourth conductive layer PEd can be formed of the same conductive material as the third connection electrode CE3 to be described below, and for example, formed of a transparent conductive material, such as indium tin oxide (ITO) or indium zinc oxide (IZO), but is not limited thereto.

Referring to FIG. 5 again, the power line VDD can be disposed on the second interlayer insulating layer 113b. The power line VDD is electrically connected to the light emitting diode LED together with the driving transistor DT to allow the light emitting diode LED to emit light. The power line VDD can be configured by a conductive material such as copper (Cu), aluminum (Al), molybdenum (Mo), nickel (Ni), titanium (Ti), chrome (Cr), or an alloy thereof, but is not limited thereto.

The passivation layer 114 can be disposed on the driving transistor DT and the power line VDD. The passivation layer 114 can protect the driving transistor DT and the power line VDD from permeation of moisture or impurity. For example, the passivation layer 114 can be configured by a single layer or a double layer of silicon oxide (SiOₓ) or silicon nitride (SiNₓ), but is not limited thereto. However, the passivation layer 114 can be omitted depending on a type of substrate 110 or a type of transistor, but is not limited thereto.

The over coating layer 115 can be disposed on the passivation layer 114. The over coating layer 115 can planarize an upper portion of the substrate 110 on which the driving transistor DT is disposed. The over coating layer 115 can be configured by a single layer or a double layer, and for example, can be formed of photoresist or an acrylic organic material, but is not limited thereto.

The plurality of reflective electrodes RE which is spaced apart from each other can be disposed on the over coating layer 115. The plurality of reflective electrodes RE can electrically connect the light emitting diode LED to the power line VDD and the driving transistor DT and serve as a reflective plate which reflects light emitted from the light emitting diode LED to the upper portion of the light emitting diode LED. The plurality of reflective electrodes RE is formed of a conductive material having the excellent reflecting property to reflect light emitted from the light emitting diode LED toward the upper portion of the light emitting diode LED. Therefore, the plurality of reflective electrodes RE can include various conductive layers in consideration of a light reflection efficiency and a resistance. For example, a reflective plate can use an opaque conductive layer, such as silver (Ag), aluminum (Al), molybdenum (Mo), titanium (Ti), or an alloy thereof, and a transparent conductive layer, such as indium tin oxide (ITO), but the structure and the material of the reflective electrode RE are not limited thereto.

The plurality of reflective electrodes RE can include a first reflective electrode RE1 and a second reflective electrode RE2. The first reflective electrode RE1 can electrically connect the driving transistor DT and the light emitting diode LED. The first reflective electrode RE1 can be connected to the source electrode SE or the drain electrode DE of the driving transistor DT through a contact hole formed in the passivation layer 114 and the over coating layer 115. The first reflective electrode RE1 can be electrically connected to the first electrode 124 of the light emitting diode LED through a first connection electrode CE1.

The second reflective electrode RE2 can electrically connect the power line VDD and the light emitting diode LED. The second reflective electrode RE2 can be connected to the power line VDD through a contact hole formed in the passivation layer 114 and the over coating layer 115 and can be electrically connected to the second electrode 125 of the light emitting diode LED through a second connection electrode CE2 and the third connection electrode to be described below.

The adhesive layer 116 is formed on the front surface of the substrate 110 on the plurality of reflective electrodes RE to fix the light emitting diodes LED disposed on the adhesive layer 116. The adhesive layer 116 can be formed of a photo curable or thermo-setting adhesive material which is hardened by light or heat. For example, the adhesive layer 116 can be formed of an acrylic material including a photoresist, but is not limited thereto.

The plurality of light emitting diodes LED can be disposed in each of the plurality of sub pixels SP on the adhesive layer 116. The plurality of light emitting diodes LED is elements which emit light by a current and can include light emitting diodes LED which emit red light, green light, and blue light and implement various colored light including white by a combination thereof. For example, the plurality of light emitting diodes LED can be light emitting diodes (LED) or micro LEDs, but is not limited thereto.

The first light emitting diode 120 can include a first semiconductor layer 121, an emission layer 122, a second semiconductor layer 123, a first electrode 124, a second electrode 125, and a passivation film 126.

The first semiconductor layer 121 can be disposed on the adhesive layer 116 and the second semiconductor layer 123 can be disposed on the first semiconductor layer 121. The first semiconductor layer 121 and the second semiconductor layer 123 can be layers formed by doping n-type and p-type impurities into a specific material. For example, the first semiconductor layer 121 and the second semiconductor layer 123 can be layers doped with n-type and p-type impurities into a material such as gallium nitride (GaN), indium aluminum phosphide (InAlP), or gallium arsenide (GaAs). The p-type impurity can be magnesium (Mg), zinc (Zn), and beryllium (Be), and the n-type impurity can be silicon (Si), germanium, and tin (Sn), but they are not limited thereto.

A part of the first semiconductor layer 121 can be disposed to outwardly protrude from the second semiconductor layer 123. A top surface of the first semiconductor layer 121 can be formed by a part overlapping a bottom surface of the second semiconductor layer 123 and a part disposed at an outside of the bottom surface of the second semiconductor layer 123. The light emitting diode LED can be a lateral light emitting diode LED. However, sizes and shapes of the first semiconductor layer 121 and the second semiconductor layer 123 can be modified in various forms, but are not limited thereto.

For example, the first semiconductor layer 121 can protrude outwardly from the second semiconductor layer 123 in some directions. The first semiconductor layer 121 can protrude to the outside of the second semiconductor layer 123 from a part of the edge of the second semiconductor layer 123. A part of the first semiconductor layer 121 can protrude outwardly from the second semiconductor layer 123 in a specific direction.

The emission layer 122 can be disposed between the first semiconductor layer 121 and the second semiconductor layer 123. The emission layer 122 can be supplied with holes and electrons from the first semiconductor layer 121 and the second semiconductor layer 123 to emit light.

The emission layer 122 can be formed by a single layer or a multi-quantum well (MQW) structure, and for example, can be formed of indium gallium nitride (InGaN) or gallium nitride (GaN), but is not limited thereto.

The first electrode 124 can be disposed on the first semiconductor layer 121. The first electrode 124 is an electrode which electrically connects the driving transistor DT and the first semiconductor layer 121. In this case, the first semiconductor layer 121 can be a semiconductor layer doped with an n-type impurity and the first electrode 124 can be a cathode. The first electrode 124 can be disposed on a top surface of the first semiconductor layer 121 which is exposed from the emission layer 122 and the second semiconductor layer 123. For example, the first electrode 124 can be disposed along a periphery of a top surface of the first semiconductor layer 121 and have a ring shape in the plan view. The first electrode 124 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 can be disposed on the second semiconductor layer 123. The second electrode 125 can be disposed on the top surface of the second semiconductor layer 123. At this time, the second semiconductor layer 123 is disposed on the first semiconductor layer 121 so that the second electrode 125 disposed on the top surface of the second semiconductor layer 123 can be disposed to be higher than the first electrode 124 disposed on the top surface of the first semiconductor layer 121. The second electrode 125 is an electrode which electrically connects the power line VDD and the second semiconductor layer 123. In this case, the second semiconductor layer 123 is a semiconductor layer doped with a p-type impurity and the second electrode 125 can be an anode. The second electrode 125 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the passivation film 126 which encloses the first semiconductor layer 121, the emission layer 122, the second semiconductor layer 123, the first electrode 124, and the second electrode 125 can be disposed. The passivation film 126 is formed of an insulating material to protect the first semiconductor layer 121, the emission layer 122, and the second semiconductor layer 123. In the passivation film 126, a contact hole which exposes the first electrode 124 and the second electrode 125 is formed to electrically connect the first connection electrode CE1 and the third connection electrode CE3 to the first electrode 124 and the second electrode 125 which will be formed later.

In the meantime, referring to FIG. 5, the second light emitting diode 130 and the third light emitting diode 140 can be disposed in substantially the same placement as the first light emitting diode 120.

The first planarization layer 117a can be disposed on the adhesive layer 116. The first planarization layer 117a is disposed so as to enclose a part of side surfaces of the plurality of light emitting diodes LED to fix and protect the plurality of light emitting diodes LED.

For example, the first planarization layer 117a can be disposed so as to enclose the passivation film 126 disposed on a lower edge of the light emitting diode LED. Therefore, the short of the first connection electrode CE1 due to the torn-out of the passivation film 126 can be suppressed. For example, during a process of separating a wafer and the light emitting diode LED, a part of the passivation film 126 can be torn out on the lower edge of the light emitting diode LED. Therefore, the passivation film 126 can expose a part of the first semiconductor layer 121 of the lower edge of the light emitting diode LED. Accordingly, a step can be caused in the lower edge of the light emitting diode LED by the torn-out passivation film 126. At this time, when the first connection electrode CE1 is disposed so as to enclose the side surface of the passivation film 126, the first connection electrode CE1 can be shorted by the step caused by the torn-out passivation film 126.

Accordingly, before placing the first connection electrode CE1, the first planarization layer 117a is disposed so as to enclose the lower edge of the light emitting diode LED so that the lower edge of the light emitting diode LED can be spaced apart from the first connection electrode CE1. Therefore, even though an under-cut structure caused by the torn-out passivation film 126 is formed on the lower edge of the light emitting diode LED, the first passivation layer 117a is in contact with at least a part of the side surface of the light emitting diode LED to be filled in the under-cut structure. Therefore, the short-circuit of the first connection electrode CE1 due to the under-cut structure can be minimized.

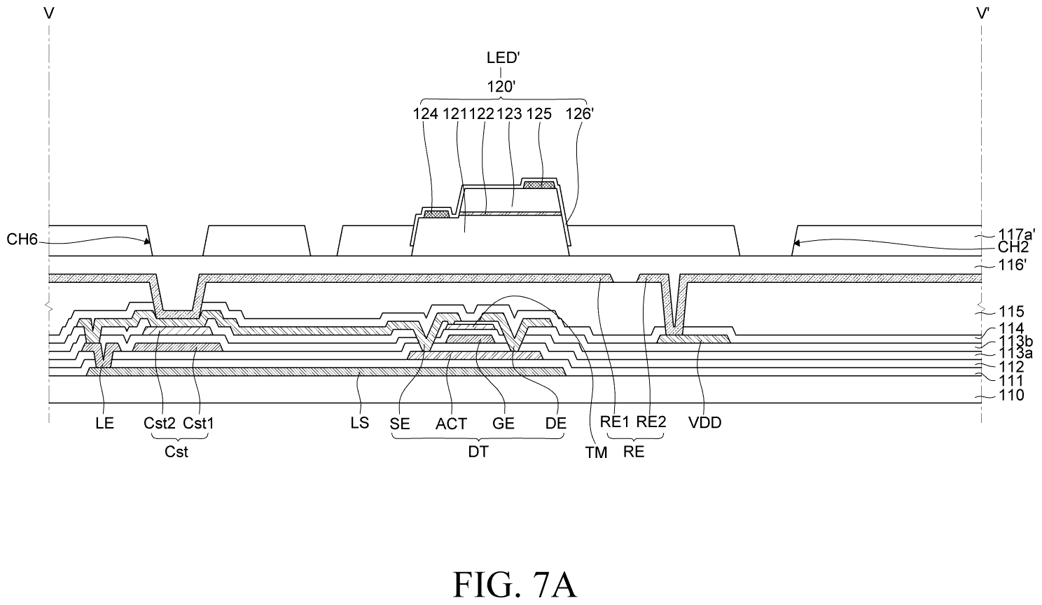

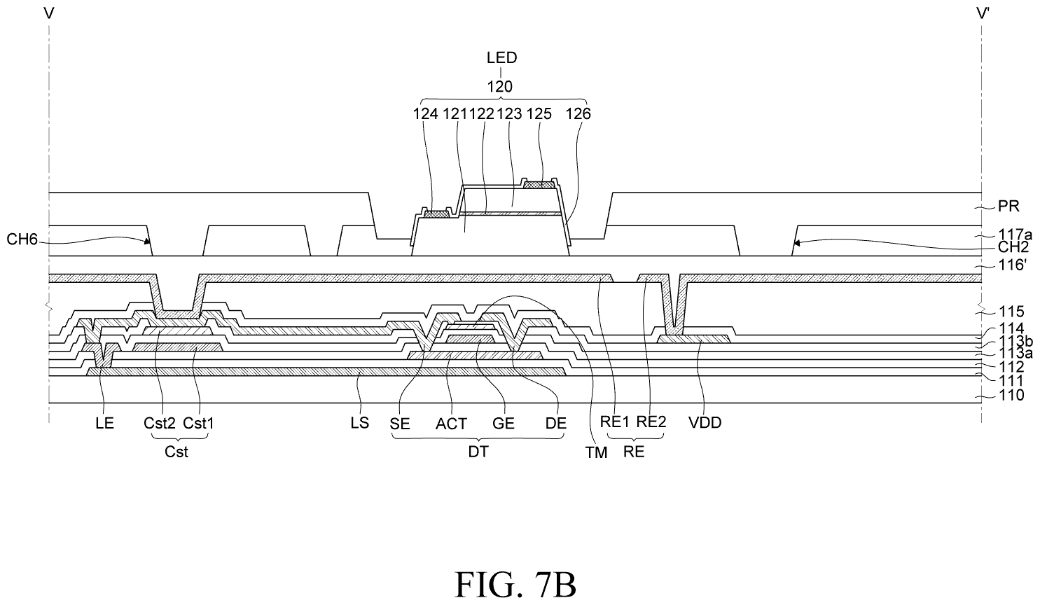

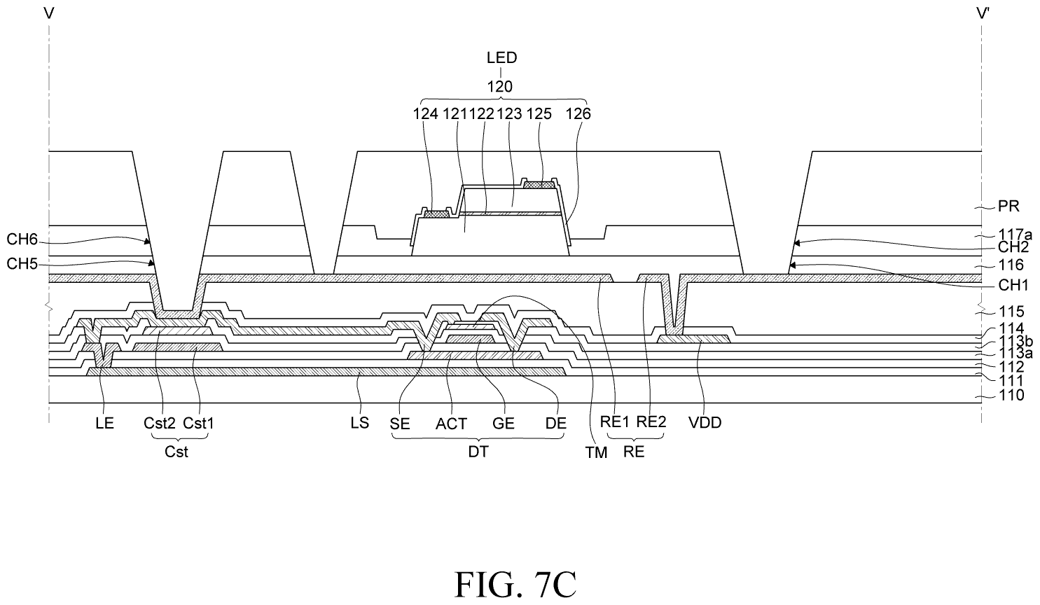

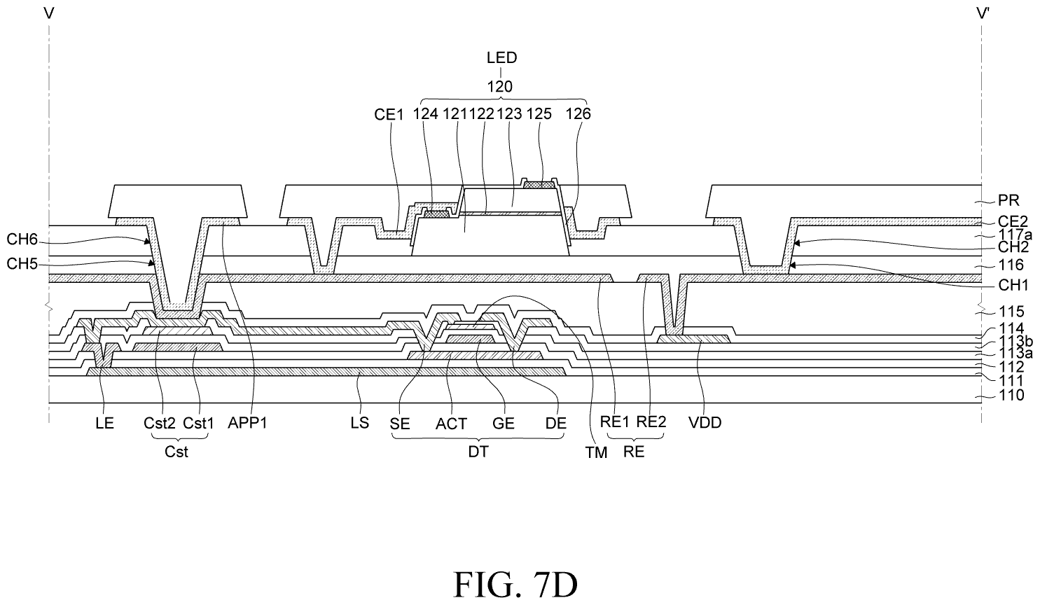

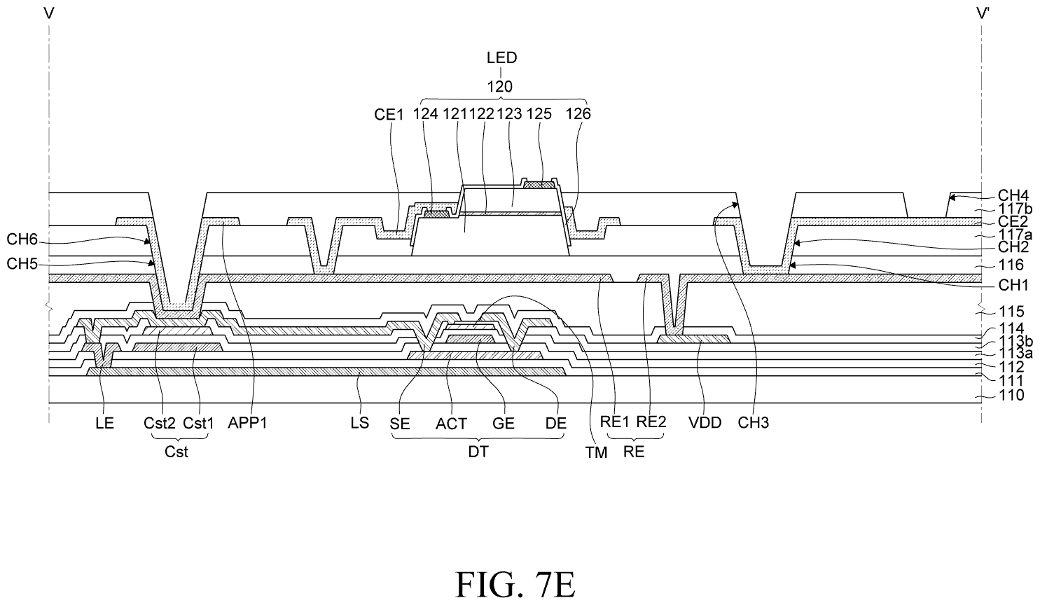

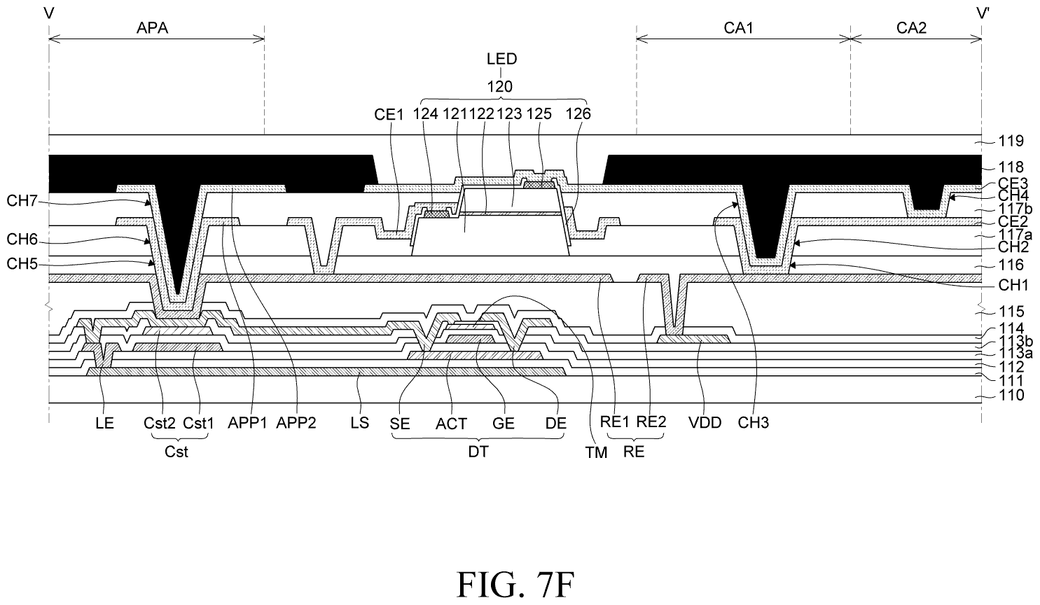

In the meantime, the first planarization layer 117a is disposed to be lower than a height of the first electrode 124 to expose the first electrode 124. Accordingly, the first connection electrode CE1 disposed on the first planarization layer 117a can be easily connected to the first electrode 124. More detailed description with regard to this will be given with reference to FIGS. 7A to 7F to be described below.

Further, the first planarization layer 117a can include a part having a relatively lower height in an area adjacent to the light emitting diode LED. For example, during a contact hole formation process of the passivation film 126 to expose the first electrode 124 and the second electrode 125, the first planarization layer 117a in an area adjacent to the light emitting diode LED is partially removed to have a part having a relatively small height. More detailed description with regard to this will be given with reference to FIGS. 7A to 7F to be described below.

The first planarization layer 117a can be configured by a single layer or a double layer, and for example, can be formed of photoresist or an acrylic organic material, but is not limited thereto.

In the meantime, the first planarization layer 117a can be lower than a height of the first electrode 124. For example, the thickness of the first planarization layer 117a can be adjusted by performing the ashing process. For example, after applying a material layer of the first planarization layer 117a so as to cover the light emitting diode LED, the ashing process is performed to reduce the overall thickness of the material layer of the first planarization layer 117a to form the height of the first planarization layer 117a to be lower than the height of the first electrode 124. Therefore, the first planarization layer 117a can expose the first electrode 124. Accordingly, the first connection electrode CE1 disposed on the first planarization layer 117a can be easily connected to the first electrode 124 without a separate contact hole.

The first connection electrode CE1 can be disposed on the first planarization layer 117a. The first connection electrode CE1 is an electrode which is disposed in each of the plurality of sub pixels SP to electrically connect the light emitting diode LED and the driving transistor DT. The first connection electrode CE1 can be connected to the first reflective electrode RE1 through the contact hole formed in the first planarization layer 117a and the adhesive layer 116. Accordingly, the first connection electrode CE1 can be electrically connected to any one of the source electrode SE and the drain electrode DE of the driving transistor DT through the first reflective electrode RE1. For example, the first connection electrode CE1 can connect the first electrode 124 of the light emitting diode LED to the source electrode SE of the driving transistor DT, but it is not limited thereto. The first connection electrode CE1 can be formed of, for example, a transparent conductive material, such as indium tin oxide (ITO) or indium zinc oxide (IZO), but is not limited thereto.

In the first contact area CA1 and the second contact area CA2, the second connection electrode CE2 can be disposed on the first planarization layer 117a. The second connection electrode CE2 is an electrode for electrically connecting the light emitting diode LED and the power line VDD. The second connection electrode CE2 can be connected to the second reflective electrode RE2 through the contact hole formed in the first planarization layer 117a and the adhesive layer 116. For example, the second connection electrode CE2 can be electrically connected to the second reflective electrode RE2 through the first contact hole CH1 of the adhesive layer 116 disposed in the first contact area CA1 and the second contact hole CH2 of the first planarization layer 117a overlapping the first contact hole CH1. Accordingly, the second connection electrode CE2 can be electrically connected to the power line VDD through the second reflective electrode RE2. For example, the second connection electrode CE2 can connect the second electrode 125 of the light emitting diode LED to the power line VDD, but it is not limited thereto.

In the meantime, the second connection electrode CE2 is disposed on the same layer as the first connection electrode CE1 to be formed of the same material, but is not limited thereto. The second connection electrode CE2 can be formed of, for example, a transparent conductive material, such as indium tin oxide (ITO) or indium zinc oxide (IZO), but is not limited thereto.

In the lighting test area APA, the first lighting test pattern APP1 can be disposed on the first planarization layer 117a. The first lighting test pattern APP1 can transmit a lighting test signal which is applied from the second lighting test pattern APP2 to the first electrode 124 of the light emitting diode LED through the first reflective electrode RE1 without passing through the driving transistor DT. The first lighting test pattern APP1 can be connected to the first reflective electrode RE1 through the contact hole formed in the first planarization layer 117a and the adhesive layer 116. For example, the first lighting test pattern APP1 can be electrically connected to the first reflective electrode RE1 through a fifth contact hole CH5 of the adhesive layer 116 disposed in the lighting test area APP and a sixth contact hole CH6 of the first planarization layer 117a overlapping the fifth contact hole CH5.

In the meantime, the first lighting test pattern APP1 is disposed on the same layer as the first connection electrode CE1 and the second connection electrode CE2 to be formed of the same material, but is not limited thereto. For example, the first lighting test pattern APP1 can be formed of a transparent conductive material, such as indium tin oxide (ITO) or indium zinc oxide (IZO). Therefore, the first lighting test pattern APP1 can be referred to as a first conductive pattern, but is not limited thereto.

The second planarization layer 117b can be disposed on the first planarization layer 117a, the plurality of first connection electrodes CE1, the plurality of second connection electrodes CE2, and the first lighting test pattern APP1. The second planarization layer 117b can planarize an upper portion of the substrate 110 on which the light emitting diode LED is disposed together with the first planarization layer 117a and fix the light emitting diode LED onto the substrate 110 together with the adhesive layer 116.

Further, the second planarization layer 117b is disposed so as to cover the first connection electrode CE1 to separate the first connection electrode CE1 from the third connection electrode CE3. Therefore, the short-circuit of the first connection electrode CE1 and the third connection electrode CE3 can be suppressed.

The second planarization layer 117b can be configured by a single layer or a double layer, and for example, similar to the first planarization layer 117a, can be formed of photoresist or an acrylic organic material, but is not limited thereto.

The third connection electrode CE3 can be disposed on the second planarization layer 117b. The third connection electrode CE3 is an electrode for electrically connecting the light emitting diode LED and the power line VDD. The third connection electrode CE3 can be connected to the second reflective electrode RE2 through the contact holes formed in the second planarization layer 117b, the first planarization layer 117a, and the adhesive layer 116. Accordingly, the third connection electrode CE3 can be electrically connected to the power line VDD through the second reflective electrode RE2. For example, the third connection electrode CE3 can connect the second electrode 125 of the light emitting diode LED to the power line VDD, but it is not limited thereto. For example, the third connection electrode CE3 can be formed of, for example, a transparent conductive material, such as indium tin oxide (ITO) or indium zinc oxide (IZO), but is not limited thereto.

For example, the third connection electrode CE3 is disposed in the first contact hole CH1 of the adhesive layer 116 disposed in the first contact area CA1, the second contact hole CH2 of the first planarization layer 117a, and the third contact hole CH3 of the second planarization layer 117b to be in contact with the second connection electrode CE2. The third contact hole CH3 overlaps the first contact hole CH1 and the second contact hole CH2. Accordingly, the third connection electrode CE3 can be electrically connected to the second reflective electrode RE2 through the second connection electrode CE2 and can be electrically connected to the power line VDD through the second reflective electrode RE2.

At this time, the third connection electrode CE3 can be additionally electrically connected to the second connection electrode CE2 in the second contact area CA2. For example, the third connection electrode CE3 is continuously disposed in the first contact area CA1 and the second contact area CA2 to be electrically connected to the second connection electrode CE2 extending from the first contact area CA1 through the fourth contact hole CH4 of the second planarization layer 117b disposed in the second contact area CA2. For example, the third connection electrode CE3 can receive the power voltage from the power line VDD, not only in the first contact area CA1, but also in the second contact area CA2, through the second connection electrode CE2. Accordingly, a resistance between the power line VDD and the third connection electrode CE3 can be reduced.

Specifically, the fourth contact hole CH4 of the second contact area CA2 may not overlap the first contact hole CH1 of the adhesive layer 116 and the second contact hole CH2 of the first planarization layer 117a, unlike the third contact hole CH3 of the first contact area CA1. Therefore, the defect caused by the residual film of the adhesive layer 116 and the first planarization layer 117a is minimized to improve the electrical connection between the third connection electrode CE3 and the second connection electrode CE2.

Further, even though in any one area of the first contact area CA1 and the second contact area CA2, the electrical connection of the second connection electrode CE2 and the third connection electrode CE3 is not formed, in the other area, the second connection electrode CE2 and the third connection electrode CE3 can be connected. Therefore, the electrical connection between the second connection electrode CE2 and the third connection electrode CE3 can be improved.

In the meantime, the third connection electrode CE3 is disposed on the second electrode 125 to be in direct contact with the second electrode 125 so that during the lighting test, the third connection electrode can directly transmit the lighting test signal to the second electrode 125 without passing through the driving transistor DT. Therefore, there is no need to separately drive the driving transistor DT, so that the defect of the light emitting diode LED can be detected regardless of the defect of the driving transistor DT.

Further, the third connection electrode CE3 can be formed before a formation process of the bank 118 to be described below. Accordingly, the defect of the light emitting diode LED can be detected before the formation process of the bank 118.

In the lighting test area APA, the second lighting test pattern APP2 can be disposed on the second planarization layer 117b. The second lighting test pattern APP2 can be in contact with the first lighting test pattern APP1 through the seventh contact hole CH7 formed in the second planarization layer 117b. For example, the second lighting test pattern APP2 may not be in contact with the first planarization layer 117a and the adhesive layer 116, but can be in contact with only the first lighting test pattern APP1. Specifically, the second lighting test pattern APP2 can be disposed on the first lighting test pattern APP1 which is exposed through the seventh contact hole CH7. At this time, the first lighting test pattern APP1 is disposed so as to enclose side surfaces of the first planarization layer 117a and the adhesive layer 116. Therefore, the second lighting test pattern APP2 which is disposed on the first lighting test pattern APP1 exposed through the seventh contact hole CH7 may not be in contact with the first planarization layer 117a and the adhesive layer 116, but can be in contact with only the first lighting test pattern APP1.

Accordingly, the second lighting test pattern APP2 can be electrically connected to the first reflective electrode RE1 through the first lighting test pattern APP1. Therefore, the lighting test signal can be directly transmitted to the first electrode 124 of the light emitting diode LED through the first reflective electrode RE1 without passing through the driving transistor DT. Therefore, there is no need to separately drive the driving transistor DT, so that the defect of the light emitting diode LED can be detected regardless of the defect of the driving transistor DT. The second lighting test pattern APP2 can be formed on the same layer as the third connection electrode CE3 to be formed with the same material, but is not limited thereto. As such, similar to the third connection electrode CE3, the second lighting test pattern APP2 is formed before the formation process of the bank 118 to be described below, so that the defect of the light emitting diode LED can be detected before the formation process of the bank 118. For example, the second lighting test pattern APP2 can be formed of a transparent conductive material, such as indium tin oxide (ITO) or indium zinc oxide (IZO). Therefore, the second lighting test pattern APP2 can also be referred to as a second conductive pattern, but is not limited thereto.

The bank 118 can be disposed on the second planarization layer 117b, the second connection electrode CE2, and the second lighting test pattern APP2. Accordingly, the bank 118 can be in direct contact with the second planarization layer 117b, the second connection electrode CE2, and the second lighting test pattern APP2, but is not limited thereto. The bank 118 is disposed so as not to overlap the light emitting diode LED to define an emission area. For example, the bank 118 covers an edge of the second connection electrode CE2 which is connected to the light emitting diode LED to define the emission area. For example, the bank 118 can divide the plurality of sub pixels SP. The bank 118 can be formed of an insulating material to insulate the second connection electrodes CE2 of adjacent sub pixels SP from each other. Further, the bank 118 can include a black component having high light absorptivity or can be configured by a black bank to suppress color mixture between adjacent sub pixels SP. The bank 118 can be formed of a polyimide resin, an acrylic resin, or a benzocyclobutene (BCB) resin, but is not limited thereto.

The third planarization layer 119 can be disposed on the second planarization layer 117b and the bank 118. The third planarization layer 119 is disposed so as to cover the top surface of the light emitting diode LED to planarize the upper portion of the substrate 110 on which the light emitting diode LED is disposed and fix and protect the light emitting diode LED. Therefore, the third planarization layer 119 can also be referred to as a protection layer or a capping layer, but is not limited thereto. The third planarization layer 119 can be configured by a single layer or a double layer, and for example, can be formed of photoresist or an acrylic organic material, but is not limited thereto.

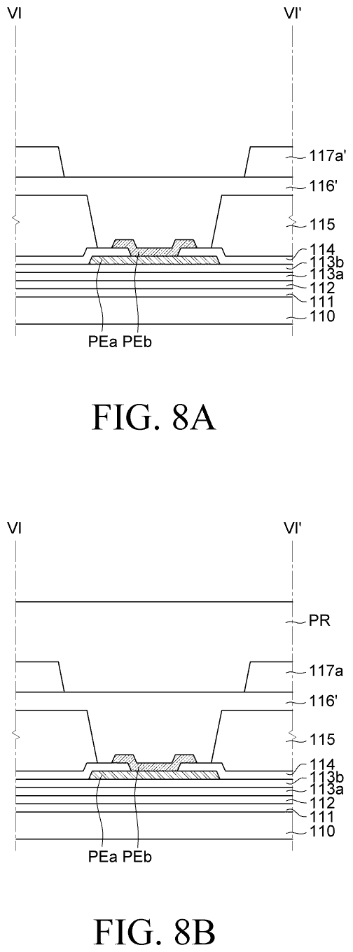

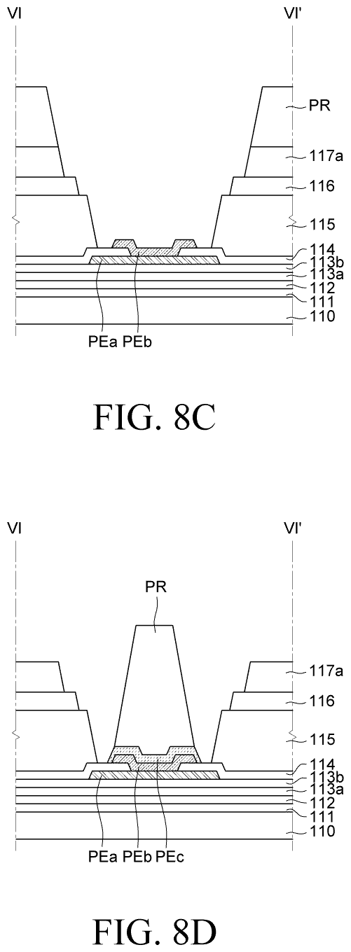

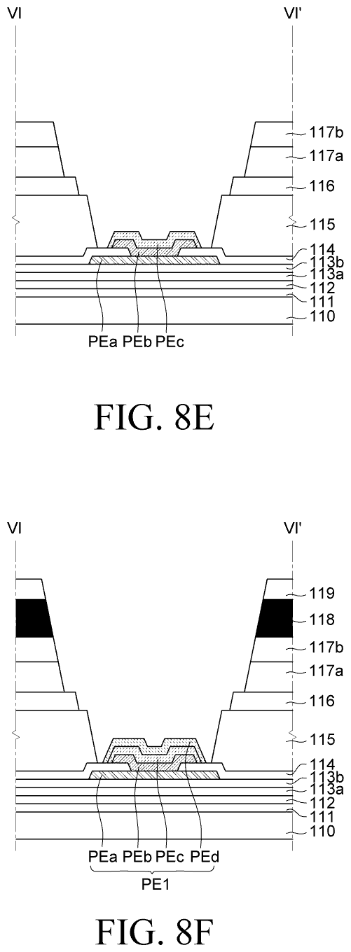

Hereinafter, a manufacturing method of a display device according to an example embodiment of the present disclosure will be described with reference to FIGS. 7A to 8F.

FIGS. 7A to 7F are process diagrams of a manufacturing method of a display device according to an example embodiment of the present disclosure and FIGS. 8A to 8F are process diagrams of a manufacturing method of a display device according to an example embodiment of the present disclosure. For example, FIGS. 7A to 7F are process diagrams for an area taken along line V-V′ of FIG. 3 and FIGS. 8A to 8F are process diagrams for an area taken along line VI-VI′ of FIG. 2A.

First, referring to FIGS. 7A and 8A, an initial light emitting diode LED′ can be disposed on an initial adhesive layer 116′ and an initial planarization layer 117a′ can be disposed on the initial adhesive layer 116′ so as to enclose the initial light emitting diode LED′.

A height of the initial first planarization layer 117a′ can be lower than a height of the first electrode 124 of the initial light emitting diode LED′. For example, the thickness of the initial first planarization layer 117a′ can be adjusted by performing the ashing process. For example, after applying a material layer of the initial first planarization layer 117a′ so as to cover the initial light emitting diode LED′, the ashing process is performed to reduce the overall thickness of the material layer of the initial first planarization layer 117a′. By doing this, the height of the initial first planarization layer 117a′ can be formed to be lower than the height of the first electrode 124. Therefore, the initial first planarization layer 117a′ can expose the first electrode 124. Accordingly, during a subsequent process, the first connection electrode CE1 disposed on the initial first planarization layer 117a′ can be easily connected to the first electrode 124.

Further, the initial first planarization layer 117a′ is partially etched to form the second contact hole CH2 and the sixth contact hole CH6. For example, the second contact hole CH2 can be a contact hole which exposes the second reflective electrode RE2 together with the first contact hole CH1 of the adhesive layer 116 which is formed in the subsequent process. The sixth contact hole CH6 can be a contact hole which exposes the first reflective electrode RE1 together with the contact hole of the adhesive layer 116 formed in the subsequent process.

In the meantime, the initial passivation film 126′ of the initial light emitting diode LED′ can be disposed so as to enclose both the first electrode 124 and the second electrode 125. The initial passivation film 126′ is partially removed during the subsequent process to become the passivation film 126.

Next, referring to FIGS. 7B and 8B, a part of the initial passivation film 126′ is etched to form a contact hole. For example, the contact hole of the passivation film 126 can be formed by a dry etching process. The contact hole which is formed at this time is a contact hole which exposes the first electrode 124 and the second electrode 125.

In the meantime, a photoresist PR may not be applied in an area of the initial first planarization layer 117a′ which is adjacent to the initial light emitting diode LED′. Accordingly, during the contact hole formation process of the passivation film 126, a part of the initial first planarization layer 117a′ which is adjacent to the initial light emitting diode LED′ can be etched together. Accordingly, an area adjacent to the initial light emitting diode LED′ is partially etched to form the first planarization layer 117a including a part with a smaller thickness only in an adjacent part which encloses the light emitting diode LED on which the photoresist PR is not applied.

Next, referring to FIGS. 7C and 8C together, a process of partially applying the photoresist PR on the first planarization layer 117a and removing a part of the initial adhesive layer 116′ on which the photoresist PR is not applied to form a contact hole can be performed. For example, the first contact hole CH1 is a contact hole which exposes the second reflective electrode RE2 and can be formed so as to overlap the second contact hole CH2. The fifth contact hole CH5 is a contact hole which exposes the first reflective electrode RE1 and can be formed so as to overlap the sixth contact hole CH6.

Referring to FIG. 8C, the initial adhesive layer 116′ which is disposed on the second conductive layer PEb can also be removed simultaneously with the formation of the first contact hole CH1 and the fifth contact hole CH5. Therefore, the second conductive layer PEb can be exposed.

Next, referring to FIGS. 7D and 8D together, a process of forming the first connection electrode CE1, the second connection electrode CE2, the first lighting test pattern APP1, and the third conductive layer PEc can be performed. For example, after placing a conductive material layer on a front surface of the substrate 110 so as to cover the light emitting diode LED, a part of the conductive material layer is removed to form the first connection electrode CE1, the second connection electrode CE2, the first lighting test pattern APP1, and the third conductive layer PEc. For example, the first connection electrode CE1, the second connection electrode CE2, the first lighting test pattern APP1, and the third conductive layer PEc can be formed of the same material.

For example, referring to FIG. 7D, the conductive material layer is disposed so as to cover the substrate 110 including the light emitting diode LED and the photoresist PR is applied. The photoresist PR disposed on a top surface of the second electrode 125, a top surface and a part of a side surface of the second semiconductor layer 123 is removed by the photo patterning and ashing processes to expose the second electrode 125. Therefore, only a part of the conductive material layer which is disposed on the top surface of the second electrode 125 and a part of the side surface and the top surface of the second semiconductor layer 123 can be exposed.

The conductive material layer which is exposed by the ashing process and a part of the conductive material layer disposed on the first planarization layer 117a are partially removed. Therefore, the first connection electrode CE1 can be self-aligned so as to be connected to only the first electrode 124 and the second connection electrode CE2 and the first lighting test pattern APP1 which are disposed to be spaced apart from the first connection electrode CE1 can be formed, simultaneously.

The second connection electrode CE2 is disposed in the first contact hole CH1 and the second contact hole CH2 which expose the second reflective electrode RE2 to connect the third connection electrode CE3 and the power line VDD in the subsequent process.

The first lighting test pattern APP1 is disposed in the fifth contact hole CH5 and the sixth contact hole CH6 which expose the first reflective electrode RE1 to be connected to the second lighting test pattern APP2 in the subsequent process to transmit the lighting test signal to the first electrode 124 of the light emitting diode LED through the first reflective electrode RE1.

In the meantime, referring to FIG. 8D, the third conductive layer PEc can be disposed on the second conductive layer PEb. The third conductive layer PEc is disposed so as to cover the end of the second conductive layer PEb to protect the second conductive layer PEb in the subsequent process.

Next, referring to FIGS. 7E and 8E together, the second planarization layer 117b can be disposed on the first connection electrode CE1, the second connection electrode CE2, the first lighting test pattern APP1, and the first planarization layer 117a′. For example, the second planarization layer 117b can be disposed to be lower than the second electrode 125 to expose the second electrode 125. For example, the thickness of the second planarization layer 117b can be adjusted by performing the ashing process. For example, after applying a material layer of the second planarization layer 117b so as to cover the light emitting diode LED, the ashing process is performed to reduce the overall thickness of the material layer of the second planarization layer 117b to form the height of the second planarization layer 117b to be lower than the height of the first electrode 125. Therefore, the second planarization layer 117b can expose the second electrode 125. Accordingly, the third connection electrode CE3 disposed on the second planarization layer 117b can be easily connected to the second electrode 125.

At this time, referring to FIG. 8E, the third conductive layer PEc can serve as a protection layer of the second conductive layer PEb. For example, during the ashing process of the second planarization layer 117b, the third conductive layer PEc serves as a mask to suppress the oxidation of the second conductive layer PEb caused by the ashing process.

Next, referring to FIG. 7F, the third connection electrode CE3 and the second lighting test pattern APP2 can be disposed on the second planarization layer 117b to be spaced apart from each other. The third connection electrode CE3 can be disposed on the light emitting diode LED and the second lighting test pattern APP2 can be disposed on the first lighting test pattern APP1.

As described above, the second planarization layer 117b is formed by performing the ashing process just until the second electrode 125 of the light emitting diode LED is exposed. Therefore, the third connection electrode CE3 disposed on the second planarization layer 117b can be in contact with only the top surface of the second electrode 125 exposed from the second planarization layer 117b. The third connection electrode CE3 can be spaced apart from the first connection electrode CE1, the emission layer 122, and the first semiconductor layer 121 disposed below the second planarization layer 117b. Therefore, the third connection electrode CE3 and the second electrode 125 can be self-aligned without ensuring the process margin.

In the meantime, the second lighting test pattern APP2 is disposed in the seventh contact hole CH7 in the second planarization layer 117b to be electrically connected to the first lighting test pattern APP1 exposed by the second contact hole CH7.

At this time, the lighting test can be performed. For example, the lighting test signal can be applied to the second lighting test pattern APP2 and the third connection electrode CE3. Therefore, the lighting test signal applied through the second lighting test pattern APP2 can be transmitted to the first electrode 124 of the light emitting diode LED through the first lighting test pattern APP1 and the first reflective electrode RE1. The lighting test signal which is applied through the third connection electrode CE3 can be transmitted to the second electrode 125 of the light emitting diode LED. Therefore, whether the light emitting diode LED is defective can be detected regardless of whether the driving transistor DT is defective.

In the meantime, referring to FIG. 8F, the fourth conductive layer PEd can be disposed on the third conductive layer PEc. The fourth conductive layer PEd is disposed so as to cover the end of the third conductive layer PEc to protect the second conductive layer PEb together with the third conductive layer PEc.

Next, referring to FIGS. 7F and 8F together, the manufacturing process of the display device 200 can be completed by placing the bank 118 and the third planarization layer 119 on the second planarization layer 117b, the third connection electrode CE3, and the second lighting test pattern APP2.

In the display device, the light emitting diode is disposed on the adhesive layer to be fixed to the substrate. In the meantime, the light emitting diode disposed on the adhesive layer can be connected to the power line and the driving transistor through the reflective electrode disposed below the adhesive layer. For example, the first electrode of the light emitting diode can be connected to the driving transistor through the first reflective electrode and the second electrode of the light emitting diode can be connected to the power line through the second reflective electrode. Therefore, in the adhesive layer, a contact hole which exposes the first reflective electrode and the second reflective electrode can be formed. However, when contact holes which expose the first reflective electrode and the second reflective electrode are simultaneously formed, the first reflective electrode or the second reflective electrode exposed by the contact holes can be damaged by the subsequent process. Therefore, the contact hole which exposes the first reflective electrode or the second reflective electrode should be formed using a separate mask by a separate process.

For example, a contact hole which exposes the first reflective electrode can be formed first so as to connect the first reflective electrode and the driving transistor. At this time, the adhesive layer can serve as a mask which protects the second reflective electrode in the subsequent process.

For example, a contact hole which exposes the first reflective electrode is formed to connect the first electrode of the light emitting diode and the first reflective electrode and then a process of ashing the planarization layer can be performed. For example, the planarization layer is ashed to expose the second electrode of the light emitting diode so as to self-align the second electrode of the light emitting diode and the connection electrode. At this time, the adhesive layer which is exposed by the planarization layer can be ashed together. However, when the adhesive layer is excessively ashed, the second reflective electrode below the adhesive layer can be exposed. Specifically, the ashing process uses plasma including oxygen so that when the reflective electrode which is formed of a material having a good reactivity, such as aluminum (Al), is exposed by the ashing process, the reflective electrode can be easily oxidized.

In contrast, when the ashing is not sufficiently performed, a contact hole of the adhesive layer which exposes the second reflective electrode may not be properly formed due to the residual film of the planarization layer or the adhesive layer, in the subsequent process. Accordingly, there can be a problem in that the second reflective electrode and the second electrode of the light emitting diode are not sufficiently electrically connected.

This problem can also occur in the process of forming the pad electrode. For example, a part of the conductive layer which configures the pad electrode can be formed of the same material as the first reflective electrode and the second reflective electrode. The conductive layer can be exposed in the process of exposing the second reflective electrode, simultaneously with the second reflective electrode. The adhesive layer can serve as a mask which protects the second reflective electrode and also serve as a mask which protects the conductive layer. However, when the adhesive layer is excessively ashed as described above, the conductive layer can be oxidized or when the adhesive layer is not sufficiently ashed, the adhesive layer may not be sufficiently electrically connected to another conductive layer which is disposed in the subsequent process.

Therefore, in the display device 100 according to the example embodiment of the present disclosure, the contact holes of the adhesive layer 116 which expose the first reflective electrode RE1 and the second reflective electrode RE2 are simultaneously formed. Further, the second connection electrode CE2 can be utilized as a protection layer of the second reflective electrode RE2. For example, a contact hole which exposes the first reflective electrode RE1 and a first contact hole CH1 which exposes the second reflective electrode can be simultaneously formed in the adhesive layer 116. Next, the first connection electrode CE1 can be disposed on the first planarization layer 117a to connect the first reflective electrode RE1 and the first electrode and the second connection electrode CE2 which is formed of the same material as the first connection electrode CE1 can be disposed on the first planarization layer 117a. At this time, the second connection electrode CE2 is disposed in the first contact hole CH1 and the second contact hole CH2 of the first planarization layer 117a which overlaps the first contact hole CH1 to be in contact with the second reflective electrode RE2. Therefore, in the subsequent process, even though the second planarization layer 117b is ashed to self-align the second electrode 125 of the light emitting diode LED and the third connection electrode CE3, the second connection electrode CE2 is disposed on the second reflective electrode RE2. Therefore, a phenomenon that the second reflective electrode RE2 is exposed by the ashing process to be oxidized can be minimized.

Likewise, in the display device 100 according to the example embodiment of the present disclosure, the adhesive layer 116 which is disposed on the second conductive layer PEb of the first pad electrode PE1 formed of the same material as the plurality of reflective electrodes RE is removed simultaneously with the formation of the contact hole of the adhesive layer 116. Therefore, the second conductive layer PEb can be exposed. Therefore, the third conductive layer PEc is disposed on the second conductive layer PEb to protect the second conductive layer PEb. Specifically, the third conductive layer PEc can be disposed so as to cover the end of the second conductive layer PEb. Accordingly, the oxidation of the second conductive layer PEb caused by the ashing process of the second planarization layer 117b can be minimized.

For example, in the display device 100 according to the example embodiment of the present disclosure, a contact hole which exposes the plurality of reflective electrodes RE and a contact hole for forming the first pad electrode PE1 are simultaneously formed in the adhesive layer 116. Therefore, not only the number of masks needed for the process can be reduced, but also the process cost and time can be saved. By doing this, the process optimization can be implemented. Further, the second connection electrode CE2 and the third conductive layer PEc are utilized as protection layers of the second reflective electrode RE2 and the second conductive layer PEb to minimize the defect that the second reflective electrode RE2 and the second conductive layer PEb are oxidized. By doing this, the reliability of the display device 100 can be improved. Specifically, the contact hole of the adhesive layer 116 is formed before placing the second planarization layer 117b so that as compared with a case that the contact hole of the adhesive layer 116 is formed after placing the second planarization layer 117b, a connection defect due to the residual film can be minimized. For example, the electrical connection between the second reflective electrode RE2 and the second connection electrode CE2 and the electrical connection between the second conductive layer PEb and the third conductive layer PEc can be improved.

Further, in the display device 100 according to the example embodiment of the present disclosure, the third connection electrode CE3 can be electrically connected to the second connection electrode CE2 through the third contact hole CH3 which overlaps the first contact hole CH1 and the second contact hole CH2. The third connection electrode CE3 can be electrically connected to the second reflective electrode RE2 through the second connection electrode RE2 and can be electrically connected to the power line VDD through the second reflective electrode RE2. Accordingly, a line resistance between the third connection electrode CE3 and the power line VDD can be reduced.

Therefore, in the display device 100 according to the example embodiment of the present disclosure, the fourth contact hole CH4 which exposes the second connection electrode CE2 is additionally formed in the second planarization layer 117b. Therefore, the third connection electrode CE3 can be additionally connected to the second connection electrode CE2 through the fourth contact hole CH4. Therefore, a resistance between the power line VDD and the third connection electrode CE3 can be more effectively reduced. Further, the fourth contact hole CH4 does not overlap the first contact hole CH1 of the adhesive layer 116 and the second contact hole CH2 of the first planarization layer 117a, unlike the third contact hole CH3, so that the connection defect due to the residual film of the adhesive layer 116 and the first planarization layer 117a can be minimized.

Further, in the display device 100 according to the example embodiment of the present disclosure, even though in any one area of the first contact area CA1 and the second contact area CA2, the electrical connection of the second connection electrode CE2 and the third connection electrode CE3 is not formed, in the other area, the second connection electrode CE2 and the third connection electrode CE3 can be connected. Therefore, the electrical connection between the second connection electrode CE2 and the third connection electrode CEC3 can be improved.

In the meantime, when the defect occurs during the manufacturing process of the display device, the plurality of pixels may not be normally lit. For example, when the light emitting diode itself is defective or the driving transistor is defective, the corresponding pixel may not be lit. Therefore, in order to perform early detection of a lighting defect which occurs during the manufacturing process of the display device, a separate lighting test can be performed. However, when the lighting test signal is applied to the light emitting diode via the driving transistor, there is a problem in that it is difficult to accurately detect only whether the light emitting diode is defective. For example, even though when the driving transistor is defective and the light emitting diode is normal, the lighting test signal should be applied to the light emitting diode via the driving transistor, it is difficult to accurately detect which one of the driving transistor and the light emitting diode is defective.

Therefore, in the display device 100 according to the example embodiment of the present disclosure, the lighting test area APA in which whether the light emitting diode LED is defective is detected regardless of the defect of the driving transistor DT can be included. For example, the first lighting test pattern APP1 can be connected to the first reflective electrode RE1 through the fifth contact hole CH5 of the adhesive layer 116 which exposes the first reflective electrode RE1 and the sixth contact hole CH6 of the first planarization layer 117a which overlaps the fifth contact hole CH5. The second lighting test pattern APP2 can be connected to the first lighting test pattern APP1 through a seventh contact hole CH7 of the second planarization layer 117b which exposes the first lighting test pattern APP1 and consequently can be connected to the first reflective electrode RE1 through the first lighting test pattern APP1. Therefore, the second lighting test pattern APP2 can transmit the lighting test signal to the first electrode 124 through the first connection electrode CE1 which is connected to the first reflective electrode RE1 without passing through the driving transistor DT. Further, the test signal can be applied to the second electrode 125 through the third connection electrode CE3. For example, in the display device 100 according to the example embodiment of the present disclosure, the lighting test of the light emitting diode LED is performed without passing through the driving transistor DT so that the defect of the light emitting diode LED itself can be detected regardless of whether the driving transistor DT is defective.

The example embodiments of the present disclosure can also be described as follows:

A display device is disclosed in the present disclosure, which can comprise a plurality of sub-pixels, and each of the plurality of sub-pixels comprises: a substrate; a driving transistor disposed on the substrate; a power line disposed on the substrate; a reflective electrode disposed on the driving transistor and the power line, wherein the reflective electrode comprises a first reflective electrode and a second reflective electrode spaced apart from each other, the first reflective electrode is electrically connected to the driving transistor, and the second reflective electrode is electrically connected to the power line; an adhesive layer disposed on the reflective electrode; a light emitting diode disposed on the adhesive layer; a first planarization layer disposed on the adhesive layer and enclosing a part of a side edge of the light emitting diode; a first connection electrode and a second connection electrode disposed on the first planarization layer and spaced apart from each other; a second planarization layer disposed on the first planarization layer, the first connection electrode and the second connection electrode; and a third connection electrode disposed on the second planarization layer, wherein the first reflective electrode is connected to the light emitting diode by the first connection electrode, and wherein the second reflective electrode is connected to the light emitting diode by the second connection electrode and the third connection electrode.

Preferably, the adhesive layer can comprise a first contact hole, the first planarization layer comprises a second contact hole, the second planarization layer comprises a third contact hole and a fourth contact hole spaced apart from each other, and the first contact hole, the second contact hole and the third contact hole are overlapped with each other; wherein the second connection electrode is electrically connected to the second reflective electrode by the first contact hole and the second contact hole, and wherein the third connection electrode is electrically connected to the second connection electrode by the first contact hole, the second contact hole and the third contact hole, and is electrically connected to the second connection electrode by the fourth contact hole, wherein the fourth contact hole is not overlapped with the first contact hole, the second contact hole or the third contact hole.

Preferably, the display device can further comprise a first interlayer insulating layer disposed on the substrate; a first pad electrode disposed on the first interlayer insulating layer; and a second interlayer insulating layer disposed on the first interlayer insulating layer, wherein the first pad electrode comprises: a first conductive layer disposed between the first interlayer insulating layer and the second interlayer insulating layer; a second conductive layer disposed on the second interlayer insulating layer; a third conductive layer disposed on the second conductive layer and covering an end of the second conductive layer; and a fourth conductive layer disposed on the third conductive layer and covering an end of the third conductive layer.

Preferably, the first conductive layer can be formed of a same conductive material as a source electrode and a drain electrode of the driving transistor, the second conductive layer can be formed of a same conductive material as the reflective electrode, the third conductive layer can be formed of a same conductive material as the first connection electrode and the second connection electrode, and the fourth conductive layer can be formed of a same conductive material as the third connection electrode.

Preferably, the light emitting diode can comprise a first semiconductor layer disposed on the adhesive layer; a second semiconductor layer disposed on the first semiconductor layer; a emission layer disposed between the first semiconductor layer and the second semiconductor layer; a first electrode disposed on the first semiconductor layer and exposed from the emission layer and the second semiconductor layer; a second electrode disposed on the second semiconductor layer; and a passivation film surrounding the first semiconductor layer, the emission layer, the second semiconductor layer, the first electrode and the second electrode, wherein the first electrode of the light emitting diode is connected to the first connection electrode, and the second electrode of the light emitting diode is connected to the third connection electrode.

Preferably, in a region adjacent to the light emitting diode, a height of the first planarization layer can be disposed to be lower than a height of the first electrode.

Preferably, the adhesive layer can further comprise a fifth contact hole, the first planarization layer can further comprise a sixth contact hole, and the fifth contact hole is overlapped with the sixth contact hole, wherein the display device further comprises: a first conductive pattern disposed on the first planarization layer and connected to the first reflective electrode by the fifth contact hole and the sixth contact hole.

Preferably, the second planarization layer can further comprise a seventh contact hole overlapped with the fifth contact hole and the sixth contact hole, wherein the display device further comprises: a second conductive pattern disposed on the second planarization layer and electrically connected to the first conductive pattern by the fifth contact hole, the sixth contact hole and the seventh contact hole.

Preferably, the first conductive pattern, the first connection electrode and the second connection electrode can be disposed on a same layer and formed of a same material, and the second conductive pattern and the third electrode can be disposed on a same layer and formed of a same material.

A display device according to aspects of the present disclosure comprises a plurality of pixels, and each of the plurality of pixels comprising a plurality of sub-pixels, wherein each of the plurality of pixels comprises a first contact region and a second contact region adjacent to each other, wherein each of the plurality of sub-pixels comprises: a substrate; a driving transistor disposed on the substrate; a power line disposed on the substrate; a reflective electrode disposed on the driving transistor and the power line, wherein the reflective electrode comprises a first reflective electrode and a second reflective electrode spaced apart from each other, the first reflective electrode is electrically connected to the driving transistor, and the second reflective electrode is electrically connected to the power line; an adhesive layer disposed on the reflective electrode; a light emitting diode disposed on the adhesive layer; a first planarization layer disposed on the adhesive layer and enclosing a part of a side edge of the light emitting diode; a first connection electrode and a second connection electrode disposed on the first planarization layer and spaced apart from each other; a second planarization layer disposed on the first planarization layer, the first connection electrode and the second connection electrode; and a third connection electrode disposed on the second planarization layer, wherein the first reflective electrode is connected to the light emitting diode by the first connection electrode, and the third connection electrode is electrically connected to the light emitting diode, wherein, in the first contact region, the second reflective electrode is electrically connected to the second connection electrode and the third connection electrode, wherein, in the second contact region, the third connection electrode is electrically connected to the second connection electrode.

Preferably, in the first contact region, the adhesive layer, the first planarization layer and the second planarization layer can comprise a first contact hole, a second contact hole and a third contact hole respectively, the first contact hole, the second contact hole and the third contact hole are overlapped with each other, and in the first contact hole, the second contact hole and the third contact hole, the second connection electrode and the third connection electrode are in contact with the second reflective electrode, and in the second contact region, the second planarization layer comprises a fourth contact hole, and in the fourth contact hole, the third connection electrode is in contact with the second connection electrode, the fourth contact hole is not overlapped with the third contact hole, the second connection electrode and or third connection electrode.

Preferably, the display device can further comprise a first interlayer insulating layer disposed on the substrate; a first pad electrode disposed on the first interlayer insulating layer; and a second interlayer insulating layer disposed on the first interlayer insulating layer, wherein the first pad electrode comprises: a first conductive layer disposed between the first interlayer insulating layer and the second interlayer insulating layer; a second conductive layer disposed on the second interlayer insulating layer; a third conductive layer disposed on the second conductive layer and covering an end of the second conductive layer; and a fourth conductive layer disposed on the third conductive layer and covering an end of the third conductive layer.

Preferably, the first conductive layer can be formed of a same conductive material as a source electrode and a drain electrode of the driving transistor, the second conductive layer can be formed of a same conductive material as the reflective electrode, the third conductive layer can be formed of a same conductive material as the first connection electrode and the second connection electrode, and the fourth conductive layer can be formed of a same conductive material as the third connection electrode.

Preferably, the light emitting diode can comprise a first semiconductor layer disposed on the adhesive layer; a second semiconductor layer disposed on the first semiconductor layer; a light emitting layer disposed between the first semiconductor layer and the second semiconductor layer; a first electrode disposed on the first semiconductor layer and exposed from the light emitting layer and the second semiconductor layer; a second electrode disposed on the second semiconductor layer; and a passivation film surrounding the first semiconductor layer, the light emitting layer, the second semiconductor layer, the first electrode and the second electrode, wherein the first electrode of the light emitting diode is connected to the first connection electrode, and the second electrode of the light emitting diode is connected to the third connection electrode.

Preferably, in a region adjacent to the light emitting diode, a height of the first planarization layer can be disposed to be lower than a height of the first electrode.

Preferably, in each of the plurality of pixels, the display device can further comprise a lighting test area spaced apart from the first contact region and the second contact region, wherein each of the plurality of sub-pixels further comprises a first lighting test pattern disposed on the first planarization layer, wherein in the lighting test area, the first lighting test pattern is electrically connected to the first reflective electrode.

Preferably, in the lighting test area, the adhesive layer and the first planarization layer can comprise a contact hole of the adhesive layer and a contact hole of the first planarization layer respectively, the contact hole of the adhesive layer and the contact hole of the first planarization layer are overlapped with each other, and the first lighting test pattern is in contact with the first reflective electrode in the contact hole of the adhesive layer and the contact hole of the first planarization layer.

Preferably, the display device can further comprise a second lighting test pattern disposed on the second planarization layer and spaced apart from the third connection electrode, wherein in the lighting test area, the second planarization layer comprises a contact hole of the second planarization layer overlapped with the contact hole of the adhesive layer and the contact hole of the first planarization layer, and in the contact hole of the adhesive layer, the contact hole of the first planarization layer and the contact hole of the second planarization layer, the second lighting test pattern is in contact with the first lighting test pattern.

Preferably, the first lighting test pattern, the first connection electrode and the second connection electrode can be disposed on a same layer and formed of a same material, and the second lighting test pattern and the third electrode can be disposed on a same layer and formed of a same material.

A display device according to aspects of the present disclosure comprises a plurality of sub-pixels, and each of the plurality of sub-pixels comprises: a substrate; a driving transistor disposed on the substrate; a first reflective electrode disposed on the driving transistor and connected to the driving transistor; an adhesive layer disposed on the first reflective electrode; a light emitting diode disposed on the adhesive layer; a first planarization layer disposed on the adhesive layer and enclosing a part of a side edge of the light emitting diode; a first connection electrode disposed on the first planarization layer; a second planarization layer disposed on the first planarization layer and the first connection electrode; and a bank layer disposed on the second planarization layer, wherein the adhesive layer comprises a contact hole of the adhesive layer, the first planarization layer comprises a contact hole of the first planarization layer, and wherein the second planarization layer comprises a contact hole of the second planarization layer overlapped with the contact hole of the adhesive layer and the contact hole of the first planarization layer, wherein the display device further comprises: a first conductive pattern disposed on the first planarization layer and connected to the first reflective electrode by the contact hole of the adhesive layer and the contact hole of the first planarization layer; and a second conductive pattern disposed between the second planarization layer and the bank layer, and electrically connected to the first conductive pattern by the contact hole of the adhesive layer, the contact hole of the first planarization layer and the contact hole of the second planarization layer, and wherein the second conductive pattern directly contacts the bank layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device comprising a plurality of sub-pixels, wherein each of the plurality of sub-pixels comprises:
a driving transistor disposed on a substrate;
a power line disposed on the substrate;
a reflective electrode disposed on the driving transistor and the power line, wherein the reflective electrode comprises a first reflective electrode and a second reflective electrode spaced apart from each other, the first reflective electrode is electrically connected to the driving transistor, and the second reflective electrode is electrically connected to the power line;
an adhesive layer disposed on the reflective electrode;
a light emitting diode disposed on the adhesive layer;
a first planarization layer disposed on the adhesive layer and disposed adjacent to a part of a side edge of the light emitting diode;
a first connection electrode and a second connection electrode disposed on the first planarization layer and spaced apart from each other;
a second planarization layer disposed on the first planarization layer, the first connection electrode and the second connection electrode; and
a third connection electrode disposed on the second planarization layer,
wherein the first reflective electrode is connected to the light emitting diode by the first connection electrode, and
wherein the second reflective electrode is connected to the light emitting diode by the second connection electrode and the third connection electrode.

2. The display device according to claim 1, wherein the adhesive layer comprises a first contact hole, the first planarization layer comprises a second contact hole, the second planarization layer comprises a third contact hole and a fourth contact hole spaced apart from each other, and the first contact hole, and the second contact hole and the third contact hole are overlapped with each other,
wherein the second connection electrode is electrically connected to the second reflective electrode by the first contact hole and the second contact hole,
wherein the third connection electrode is electrically connected to the second connection electrode by the first contact hole, the second contact hole and the third contact hole, and is electrically connected to the second connection electrode by the fourth contact hole, and
wherein the fourth contact hole is not overlapped with the first contact hole, the second contact hole or the third contact hole.

3. The display device according to claim 1, further comprising:
a first interlayer insulating layer disposed on the substrate;
a first pad electrode disposed on the first interlayer insulating layer; and
a second interlayer insulating layer disposed on the first interlayer insulating layer,
wherein the first pad electrode comprises:
a first conductive layer disposed between the first interlayer insulating layer and the second interlayer insulating layer;
a second conductive layer disposed on the second interlayer insulating layer;
a third conductive layer disposed on the second conductive layer and covering an end of the second conductive layer; and
a fourth conductive layer disposed on the third conductive layer and covering an end of the third conductive layer.

4. The display device according to claim 3, wherein the first conductive layer includes a same conductive material as a source electrode and a drain electrode of the driving transistor, the second conductive layer includes a same conductive material as the reflective electrode, the third conductive layer includes a same conductive material as the first connection electrode and the second connection electrode, and the fourth conductive layer includes a same conductive material as the third connection electrode.

5. The display device according to claim 1, wherein the light emitting diode comprises:
a first semiconductor layer disposed on the adhesive layer;
a second semiconductor layer disposed on the first semiconductor layer;
a emission layer disposed between the first semiconductor layer and the second semiconductor layer;
a first electrode disposed on the first semiconductor layer and exposed from the emission layer and the second semiconductor layer;
a second electrode disposed on the second semiconductor layer; and
a passivation film surrounding the first semiconductor layer, the emission layer, the second semiconductor layer, the first electrode and the second electrode,
wherein the first electrode of the light emitting diode is connected to the first connection electrode, and the second electrode of the light emitting diode is connected to the third connection electrode.

6. The display device according to claim 5, wherein in a region adjacent to the light emitting diode, a height of the first planarization layer is disposed to be lower than a height of the first electrode.

7. The display device according to claim 1, wherein the adhesive layer further comprises a fifth contact hole, the first planarization layer further comprises a sixth contact hole, and the fifth contact hole is overlapped with the sixth contact hole,
wherein the display device further comprises:
a first conductive pattern disposed on the first planarization layer and connected to the first reflective electrode by the fifth contact hole and the sixth contact hole.

8. The display device according to claim 7, wherein the second planarization layer further comprises a seventh contact hole overlapped with the fifth contact hole and the sixth contact hole,
wherein the display device further comprises:
a second conductive pattern disposed on the second planarization layer and electrically connected to the first conductive pattern by the fifth contact hole, the sixth contact hole and the seventh contact hole.

9. The display device according to claim 8, wherein the first conductive pattern, the first connection electrode and the second connection electrode are disposed on a same layer and include a same material, and the second conductive pattern and the third electrode are disposed on a same layer and include a same material.

10. A display device comprising a plurality of pixels, each of the plurality of pixels comprising a plurality of sub-pixels,
wherein each of the plurality of pixels comprises a first contact region and a second contact region disposed adjacent to each other,
wherein each of the plurality of sub-pixels comprises:
a driving transistor disposed on a substrate;
a power line disposed on the substrate;
a reflective electrode disposed on the driving transistor and the power line, wherein the reflective electrode comprises a first reflective electrode and a second reflective electrode spaced apart from each other, the first reflective electrode is electrically connected to the driving transistor, and the second reflective electrode is electrically connected to the power line;
an adhesive layer disposed on the reflective electrode;
a light emitting diode disposed on the adhesive layer;
a first planarization layer disposed on the adhesive layer and disposed adjacent to a part of a side edge of the light emitting diode;
a first connection electrode and a second connection electrode disposed on the first planarization layer and spaced apart from each other;
a second planarization layer disposed on the first planarization layer, the first connection electrode and the second connection electrode; and
a third connection electrode disposed on the second planarization layer,
wherein the first reflective electrode is connected to the light emitting diode by the first connection electrode, and the third connection electrode is electrically connected to the light emitting diode,
wherein, in the first contact region, the second reflective electrode is electrically connected to the second connection electrode and the third connection electrode, and
wherein, in the second contact region, the third connection electrode is electrically connected to the second connection electrode.

11. The display device according to claim 10, wherein in the first contact region, the adhesive layer, the first planarization layer and the second planarization layer comprise a first contact hole, a second contact hole and a third contact hole respectively, the first contact hole, the second contact hole and the third contact hole are overlapped with each other, and in the first contact hole, the second contact hole and the third contact hole, the second connection electrode and the third connection electrode are in contact with the second reflective electrode, and
wherein in the second contact region, the second planarization layer comprises a fourth contact hole, and in the fourth contact hole, the third connection electrode is in contact with the second connection electrode, the fourth contact hole is not overlapped with the third contact hole, the second connection electrode and or third connection electrode.

12. The display device according to claim 10, further comprising:
a first interlayer insulating layer disposed on the substrate;
a first pad electrode disposed on the first interlayer insulating layer; and
a second interlayer insulating layer disposed on the first interlayer insulating layer,
wherein the first pad electrode comprises:
a first conductive layer disposed between the first interlayer insulating layer and the second interlayer insulating layer;
a second conductive layer disposed on the second interlayer insulating layer;
a third conductive layer disposed on the second conductive layer and covering an end of the second conductive layer; and
a fourth conductive layer disposed on the third conductive layer and covering an end of the third conductive layer.

13. The display device according to claim 12, wherein the first conductive layer includes a same conductive material as a source electrode and a drain electrode of the driving transistor, the second conductive layer includes a same conductive material as the reflective electrode, the third conductive layer includes a same conductive material as the first connection electrode and the second connection electrode, and the fourth conductive layer includes a same conductive material as the third connection electrode.

14. The display device according to claim 10, wherein the light emitting diode comprises:
a first semiconductor layer disposed on the adhesive layer;
a second semiconductor layer disposed on the first semiconductor layer;
a light emitting layer disposed between the first semiconductor layer and the second semiconductor layer;
a first electrode disposed on the first semiconductor layer and exposed from the light emitting layer and the second semiconductor layer;
a second electrode disposed on the second semiconductor layer; and
a passivation film surrounding the first semiconductor layer, the light emitting layer, the second semiconductor layer, the first electrode and the second electrode,
wherein the first electrode of the light emitting diode is connected to the first connection electrode, and the second electrode of the light emitting diode is connected to the third connection electrode.

15. The display device according to claim 14, wherein in a region adjacent to the light emitting diode, a height of the first planarization layer is disposed to be lower than a height of the first electrode.

16. The display device of claim 10, wherein in each of the plurality of pixels, the display device further comprises a lighting test area spaced apart from the first contact region and the second contact region,
wherein each of the plurality of sub-pixels further comprises a first lighting test pattern disposed on the first planarization layer, and
wherein in the lighting test area, the first lighting test pattern is electrically connected to the first reflective electrode.

17. The display device according to claim 16, wherein in the lighting test area, the adhesive layer and the first planarization layer comprise a contact hole of the adhesive layer and a contact hole of the first planarization layer respectively, the contact hole of the adhesive layer and the contact hole of the first planarization layer are overlapped with each other, and the first lighting test pattern is in contact with the first reflective electrode in the contact hole of the adhesive layer and the contact hole of the first planarization layer.

18. The display device according to claim 17, further comprising:
a second lighting test pattern disposed on the second planarization layer and spaced apart from the third connection electrode,
wherein in the lighting test area, the second planarization layer comprises a contact hole of the second planarization layer overlapped with the contact hole of the adhesive layer and the contact hole of the first planarization layer, and
wherein in the contact hole of the adhesive layer, the contact hole of the first planarization layer and the contact hole of the second planarization layer, the second lighting test pattern is in contact with the first lighting test pattern.

19. The display device according to claim 18, wherein the first lighting test pattern, the first connection electrode and the second connection electrode are disposed on a same layer and include a same material, and the second lighting test pattern and the third electrode are disposed on a same layer and formed of a same material.

20. A display device comprising a plurality of sub-pixels, wherein each of the plurality of sub-pixels comprises:
a substrate;
a driving transistor disposed on the substrate;
a first reflective electrode disposed on the driving transistor and connected to the driving transistor;
an adhesive layer disposed on the first reflective electrode;
a light emitting diode disposed on the adhesive layer;
a first planarization layer disposed on the adhesive layer and enclosing a part of a side edge of the light emitting diode;
a first connection electrode disposed on the first planarization layer;
a second planarization layer disposed on the first planarization layer and the first connection electrode; and
a bank layer disposed on the second planarization layer,
wherein the adhesive layer comprises a contact hole of the adhesive layer, the first planarization layer comprises a contact hole of the first planarization layer,
wherein the second planarization layer comprises a contact hole of the second planarization layer overlapped with the contact hole of the adhesive layer and the contact hole of the first planarization layer,
wherein the display device further comprises:
a first conductive pattern disposed on the first planarization layer and connected to the first reflective electrode by the contact hole of the adhesive layer and the contact hole of the first planarization layer; and
a second conductive pattern disposed between the second planarization layer and the bank layer, and electrically connected to the first conductive pattern by the contact hole of the adhesive layer, the contact hole of the first planarization layer and the contact hole of the second planarization layer, and
wherein the second conductive pattern directly contacts the bank layer.
